(19) United States
(12) Patent Application Publication
(10) Pub. No.: US 2025/0131949 A1
(43) Pub. Date: Apr. 24, 2025

(54) Storage Device

(71) Applicant: Semiconductor Energy Laboratory Co., Ltd., Kanagawa-ken (JP)

(72) Inventors: Shunpei YAMAZAKI, Setagaya, Tokyo (JP); Tatsuya ONUKI, Atsugi, Kanagawa (JP); Kiyoshi KATO, Atsugi, Kanagawa (JP); Hitoshi KUNITAKE, Machida, Tokyo (JP); Ryota HODO, Atsugi, Kanagawa (JP)

(73) Assignee: Semiconductor Energy Laboratory Co., Ltd., Kanagawa-ken (JP)

(21) Appl. No.: 18/832,322

(22) PCT Filed: Jan. 16, 2023
(86) PCT No.: PCT/IB2023/050352

§ 371 Date: Jul. 23, 2024

(30) Foreign Application Priority Data
Jan. 28, 2022 (JP) 2022-012185

(51) Int. Cl. G11C 5/10

(52) U.S. Cl. CPC G11C 5/10

(57) ABSTRACT

A novel storage device is provided. A storage device in which N memory layers each including a plurality of memory cells provided in a matrix (Nis an integer greater than or equal to 2) are stacked is provided. A write bit line, a read bit line, and a selection line are provided along a stacking direction of the memory layers, and a write word line and a read word line are provided in the direction orthogonal to the stacking direction of the memory layers. The memory cell includes a first transistor, a second transistor, and a capacitor. One of a source and a drain of the first transistor is electrically connected to the write bit line through a first conductor including a region functioning as one of a source electrode and a drain electrode. The first conductor includes a region where at least one of the top surface, a side surface, and the bottom surface of the first conductor is in contact with the write bit line.

### TECHNICAL FIELD

One embodiment of the present invention relates to a storage device.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter.

Thus, examples of the technical field of one embodiment of the present invention include a semiconductor device, a display apparatus, a liquid crystal display apparatus, a light-emitting apparatus, a power storage device, an image capturing device, a storage device, a signal processing device, a processor, an electronic device, a system, a driving method thereof, a manufacturing method thereof, a testing method thereof, and a usage method thereof.

### BACKGROUND ART

In recent years, semiconductor devices such as LSI, CPUs, and memories (storage devices) have been developed. These semiconductor devices have been used in various electronic devices such as computers and portable information terminals. In addition, memories under development employ various memory systems for intended uses such as temporary storage at the time of executing arithmetic processing and long-term storage of data. Examples of memories with typical memory systems include a DRAM, an SRAM, and a flash memory.

With the increase in the amount of data dealt with, semiconductor devices having a larger storage capacity have been required. Patent Document 1 and Non-Patent Document 1 disclose memory cells in which transistors are stacked.

### REFERENCES PATENT

### Document Patent

Document 1PCT International Publication No. 2021/053473

### Non-Patent Document

[Non-Patent Document 1] M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a storage device having a large storage capacity. Another object is to provide a storage device that occupies a small area. Another object is to provide a storage device with high reliability. Another object is to provide a storage device with low power consumption. Another object is to provide a novel storage device.

Note that the objects of one embodiment of the present invention are not limited to the objects listed above. The objects listed above do not preclude the existence of other objects. The other objects are objects that are not described in this section and will be described below. The objects that are not described in this section will be derived from the description of the specification, the drawings, and the like and can be extracted as appropriate from the description by those skilled in the art. One embodiment of the present invention does not have to achieve all of the objects listed above and the other objects. One embodiment of the present invention achieves at least one of the objects listed above and the other objects.

### Means for Solving the Problems

One embodiment of the present invention is a storage device including N memory layers (N is an integer greater than or equal to 2), a plurality of first wirings extending in a first direction (e.g., Z direction) that is a stacking direction of the N memory layers, a plurality of second wirings extending in the first direction, a plurality of third wirings extending in the first direction, a plurality of fourth wirings extending in a second direction orthogonal to the first direction (e.g., X direction or Y direction), and a plurality of fifth wirings extending in the second direction. Each of the N memory layers includes a plurality of memory cells arranged in a matrix. Each of the plurality of memory cells includes a first transistor, a second transistor, and a capacitor. A gate of the first transistor is electrically connected to one of the plurality of fourth wirings. One of a source and a drain of the first transistor is electrically connected to the first wiring through a first conductor. One electrode of the capacitor is electrically connected to the fifth wiring. The one electrode of the capacitor is electrically connected to the other of the source and the drain of the first transistor and a gate of the second transistor. One of a source and a drain of the second transistor is electrically connected to the second wiring. The other of the source and the drain of the second transistor is electrically connected to the third wiring. The first conductor includes a region where at least one of a top surface, a side surface, and a bottom surface of the first conductor is in contact with the first wiring.

The one of the source and the drain of the second transistor may be electrically connected to the second wiring through a second conductor. The second conductor preferably includes a region where at least one of a top surface, a side surface, and a bottom surface of the second conductor is in contact with the second wiring.

The other of the source and the drain of the second transistor may be electrically connected to the third wiring through a third conductor. The third conductor preferably includes a region where at least one of a top surface, a side surface, and a bottom surface of the third conductor is in contact with the third wiring.

The first transistor is preferably a transistor including a back gate. The first transistor is preferably a transistor including an oxide semiconductor.

### Effect of the Invention

One embodiment of the present invention can provide a storage device with a high storage capacity. Alternatively, a storage device that occupies a small area can be provided. Alternatively, a highly reliable storage device can be provided. Alternatively, a storage device with low power consumption can be provided. Alternatively, a novel storage device can be provided.

Note that the effects of one embodiment of the present invention are not limited to the effects listed above. The effects listed above do not preclude the existence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1A is a perspective view illustrating a structure example of a transistor. FIG. 1B is a block diagram illustrating a structure example of the semiconductor device.

FIG. 2A is an enlarged perspective block diagram of part of a memory layer. FIG. 2B is a plan view of the part of the memory layer seen from the Z direction.

FIG. 3A is a schematic cross-sectional view of a memory cell. FIG. 3B illustrates a circuit structure example of the memory cell.

FIG. 4 is a diagram illustrating an example of a cross-sectional structure of a memory layer.

FIG. 5 is a diagram illustrating a circuit structure example of memory layers.

FIG. 6 is a timing chart for illustrating an operation example of a memory cell 10.

FIGS. 7A and 7B are circuit diagrams for illustrating an operation example of the memory cell 10.

FIGS. 8A and 8B are circuit diagrams for illustrating an operation example of the memory cell 10.

FIG. 9A to FIG. 9D are diagrams illustrating a structure example of a semiconductor device.

FIG. 10 is a diagram illustrating a structure example of a semiconductor device.

FIG. 11A to FIG. 11C are diagrams illustrating structure examples of a semiconductor device.

FIGS. 12A and 12B are diagrams illustrating a structure example of a semiconductor device.

FIGS. 13A and 13B are diagrams illustrating structure examples of a semiconductor device.

FIG. 14A to FIG. 14D are diagrams illustrating a structure example of a semiconductor device.

FIG. 15 is a diagram illustrating a structure example of a semiconductor device.

FIGS. 16A and 16B are perspective views illustrating examples of electronic devices.

FIG. 17A to FIG. 17J are diagrams illustrating examples of electronic devices.

FIG. 18A to FIG. 18E are diagrams illustrating examples of electronic devices.

FIG. 19A to FIG. 19C are diagrams each illustrating an example of an electronic device.

### MODE FOR CARRYING OUT THE INVENTION

Hereinafter, embodiments described in this specification are described with reference to the drawings. Note that the embodiments can be implemented in many different modes, and it will be readily understood by those skilled in the art that the modes and details can be changed in various ways without departing from the spirit and scope thereof. Therefore, the present invention should not be interpreted as being limited to the description in the embodiments. Note that in the structures of the invention in the embodiments, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases. Moreover, some components are omitted in a perspective view, a top view, and the like for easy understanding of the drawings in some cases.

In addition, in the drawings and the like in this specification and the like, the size, the layer thickness, or the region is exaggerated for clarity in some cases. Therefore, embodiments of the present invention are not limited to the size, aspect ratio, and the like illustrated in the drawings. Note that the drawings schematically illustrate ideal examples, and embodiments of the present invention are not limited to shapes, values, and the like illustrated in the drawings. For example, variation in signal, voltage, or current due to noise or variation in signal, voltage, or current due to difference in timing can be included.

In this specification, a semiconductor device refers to a device that utilizes semiconductor characteristics, and means a circuit including a semiconductor element (a transistor, a diode, a photodiode, and the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a storage device, a display apparatus, a light-emitting apparatus, a lighting device, an electronic device, and the like themselves might be semiconductor devices, or might include semiconductor devices.

In the case where there is description “X and Y are connected” in this specification and the like, a case where X and Y are electrically connected, a case where X and Y are functionally connected, and a case where X and Y are directly connected are regarded as being disclosed in this specification and the like. Accordingly, without being limited to a predetermined connection relationship, e.g., a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, a layer, or the like).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y.

For example, in the case where X and Y are functionally connected, one or more circuits that allow functional connection between X and Y (e.g., a logic circuit (an inverter, a NAND circuit, a NOR circuit, or the like); a signal converter circuit (a digital-analog converter circuit, an analog-digital converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; a control circuit; or the like) can be connected between X and Y. For instance, even if another circuit is provided between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order”. Alternatively, it can be expressed that “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit structure is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Therefore, in this specification and the like, a “capacitor” includes not only a circuit element that has a pair of electrodes and a dielectric between the electrodes, but also parasitic capacitance generated between wirings, gate capacitance generated between a gate and one of a source and a drain of a transistor, and the like. The terms “capacitor”, “parasitic capacitance”, “gate capacitance”, and the like can be replaced with the term “capacitance” and the like; conversely, the term “capacitance” can be replaced with the terms “capacitor”, “parasitic capacitance”, “gate capacitance”, and the like. The term “pair of electrodes” of “capacitor” can be replaced with “pair of conductors”, “pair of conductive regions”, “pair of regions”, and the like. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the amount of current flowing between the source and the drain. Two terminals functioning as the source and the drain are input/output terminals of the transistor. One of the two input/output terminals serves as the source and the other serves as the drain depending on the conductivity type (n-channel type or p-channel type) of the transistor and the levels of potentials supplied to the three terminals of the transistor. Thus, the terms “source” and “drain” can be replaced with each other in this specification and the like.

Note that in this specification and the like, a gate refers to part or all of a gate electrode and a gate wiring. A gate wiring refers to a wiring for electrically connecting a gate electrode of at least one transistor to another electrode or another wiring, and for example, the gate wiring also includes a scan line in a display apparatus.

A source refers to part or all of a source region, a source electrode, or a source wiring. A source region refers to a region in a semiconductor layer where the resistivity is lower than or equal to a given value. A source electrode refers to a conductive layer including part connected to a source region. A source wiring is a wiring for electrically connecting a source electrode of at least one transistor to another electrode or another wiring. For example, in the case where a signal line in a display apparatus is electrically connected to a source electrode, the source wiring includes the signal line in its category.

A drain refers to part or all of a drain region, a drain electrode, or a drain wiring. A drain region refers to a region in a semiconductor layer where the resistivity is lower than or equal to a given value. A drain electrode refers to a conductive layer including part connected to a drain region. A drain wiring is a wiring for electrically connecting a drain electrode of at least one transistor to another electrode or another wiring. For example, in the case where a signal line in a display apparatus is electrically connected to a drain electrode, the drain wiring includes the signal line in its category.

Furthermore, in this specification and the like, expressions “one of a source and a drain” (or a first electrode or a first terminal) and “the other of the source and the drain” (or a second electrode or a second terminal) are used in some cases in the description of the connection relation of a transistor. Depending on the transistor structure, a transistor may include a back gate in addition to the above three terminals. In that case, in this specification and the like, one of the gate and the back gate of the transistor is sometimes referred to as a first gate, and the other of the gate and the back gate of the transistor is sometimes referred to as a second gate. Moreover, the terms “gate” and “back gate” can be replaced with each other in one transistor in some cases. In the case where a transistor includes three or more gates, the gates may be referred to as a first gate, a second gate, and a third gate in this specification and the like.

In this specification and the like, a “node” can be referred to as a “terminal”, a “wiring”, an “electrode”, a “conductive layer”, a “conductor”, an “impurity region”, or the like depending on the circuit structure, the device structure, or the like. Furthermore, a “terminal”, a “wiring”, or the like can be referred to as a “node”.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. As another example, a “first” component in one embodiment in this specification and the like can be omitted in other embodiments or the scope of claims.

In this specification and the like, terms for describing arrangement, such as “over”, “under”, “above”, and “below” are sometimes used for convenience to describe the positional relationship between components with reference to drawings. The positional relationship between components is changed as appropriate in accordance with a direction in which each component is described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

Furthermore, the term “over” or “under” does not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B.

Furthermore, the term “overlap”, for example, in this specification and the like does not limit a state such as the stacking order of components. For example, the expression “the electrode B overlapping with the insulating layer A” does not necessarily mean the state where “the electrode B is formed over the insulating layer A”, and does not exclude the state where “the electrode B is formed under the insulating layer A” and the state where “the electrode B is formed on the right side (or the left side) of the insulating layer A”.

The term “adjacent” or “proximity” in this specification and the like does not necessarily mean that a component is directly in contact with another component. For example, the expression “the electrode B adjacent to the insulating layer A” does not necessarily mean that the electrode B is formed in direct contact with the insulating layer A and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. Also, for example, the term “insulating film” can be changed into the term “insulating layer” in some cases. Alternatively, the term “film”, “layer”, or the like is not used and can be interchanged with another term depending on the case or the situation. For example, the term “conductive layer” or “conductive film” can be changed into the term “conductor” in some cases. Alternatively, the term “conductor” can be changed into the term “conductive layer” or “conductive film” in some cases. As another example, the term “insulating layer” or “insulating film” can be changed into the term “insulator” in some cases. Alternatively, the term “insulator” can be changed into the term “insulating layer” or “insulating film” in some cases.

In this specification and the like, the term such as “electrode”, “wiring”, or “terminal” does not limit the function of a component. For example, an “electrode” is used as part of a “wiring” in some cases, and vice versa. Furthermore, for example, the term “electrode” or “wiring” also includes the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the terms “electrode”, “wiring”, “terminal”, and the like are sometimes replaced with the term “region” or the like.

In addition, in this specification and the like, the terms such as “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line”, “power supply line”, or the like can be changed into the term “wiring” in some cases. The term “power supply line” or the like can be changed into the term “signal line” or the like in some cases. Conversely, the term “signal line” or the like can be changed into the term “power supply line” or the like in some cases. The term “potential” that is applied to a wiring can be changed into the term “signal” or the like depending on the case or the situation. Conversely, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether current flows therethrough or not. Alternatively, a switch has a function of selecting and changing a current path. For example, an electrical switch or a mechanical switch can be used. That is, a switch can be any element capable of controlling current, and is not limited to a particular element.

Examples of a switch include a transistor (e.g., a bipolar transistor or a MOS transistor), a diode (e.g., a PN diode, a PIN diode, a Schottky diode, a MIM (Metal Insulator Metal) diode, a MIS (Metal Insulator Semiconductor) diode, or a diode-connected transistor), and a logic circuit in which such elements are combined. Note that in the case where a transistor is used as a switch, a “conduction state” of the transistor refers to a state where a source electrode and a drain electrode of the transistor can be regarded as being electrically short-circuited. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically, and selects a conduction or non-conduction with the movement of the electrode.

Note that in this specification and the like, the “on state” (sometimes abbreviated as “on”) of a transistor refers to a state where a source and a drain of the transistor are electrically short-circuited (also referred to as a “conduction state”). Unless otherwise specified, an “on state” refers to a state where the voltage between a gate and a source (also referred to as “gate voltage” or “Vg”) is higher than or equal to threshold voltage (also referred to as “Vth”) in an n-channel transistor, and refers to a state where Vg is lower than or equal to Vth in a p-channel transistor.

Furthermore, the “off state” (sometimes abbreviated as “off”) of a transistor refers to a state where a source and a drain of the transistor are electrically disconnected (also referred to as a “non-conduction state”). Unless otherwise specified, an “off state” refers to a state where the Vg is lower than Vth in an n-channel transistor, and refers to a state where Vg is higher than Vth in a p-channel transistor.

In addition, in this specification and the like, “on-state current” sometimes refers to current that flows between a source and a drain when a transistor is in an on state. Furthermore, “off-state current” sometimes refers to current that flows between a source and a drain when a transistor is in an off state.

In this specification and the like, a high power supply potential VDD (hereinafter, also simply referred to as “potential VDD” or “VDD”) is a power supply potential higher than a low power supply potential VSS (hereinafter, also simply referred to as “potential VSS” or “VSS”). The low power supply potential VSS is a power supply potential lower than the high power supply potential VDD.

When a potential H (hereinafter, also simply referred to as “H”) is supplied to a gate of an n-channel transistor, the transistor is brought into an on state. When a potential L (hereinafter, also simply referred to as “L”) is supplied to the gate of the n-channel transistor, the transistor is brought into an off state. Accordingly, the potential H is a potential higher than the potential L. Unless otherwise specified, the potential H and VDD may be the same potential. The potential L is a potential lower than the potential H. Unless otherwise specified, the potential L and the potential VSS may be the same potential.

In addition, a ground potential can be used as VDD or VSS. For example, in the case where VDD is the ground potential, VSS is a potential lower than the ground potential, and in the case where VSS is the ground potential, VDD is a potential higher than the ground potential.

In this specification and the like, a gate refers to part or the whole of a gate electrode and a gate wiring. A gate wiring refers to a wiring for electrically connecting a gate electrode of at least one transistor to another electrode or another wiring.

In this specification and the like, a source refers to part or the whole of a source region, a source electrode, and a source wiring. A source region refers to a region in a semiconductor layer where the resistivity is lower than or equal to a given value. A source electrode refers to a conductive layer including part connected to a source region. A source wiring refers to a wiring for electrically connecting a source electrode of at least one transistor to another electrode or another wiring.

In this specification and the like, a drain refers to part or the whole of a drain region, a drain electrode, and a drain wiring. A drain region refers to a region in a semiconductor layer where the resistivity is lower than or equal to a given value. A drain electrode refers to a conductive layer including part connected to a drain region. A drain wiring refers to a wiring for electrically connecting a drain electrode of at least one transistor to another electrode or another wiring.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

Note that in this specification and the like, the terms “identical”, “the same”, “equal”, “uniform”, and the like (including synonyms thereof) used in describing calculation values and measurement values contain an error of +20% unless otherwise specified.

In the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals.

### Embodiment 1

A structure example of a storage device 100 including the memory cell 10 (also referred to as a “memory element”) will be described.

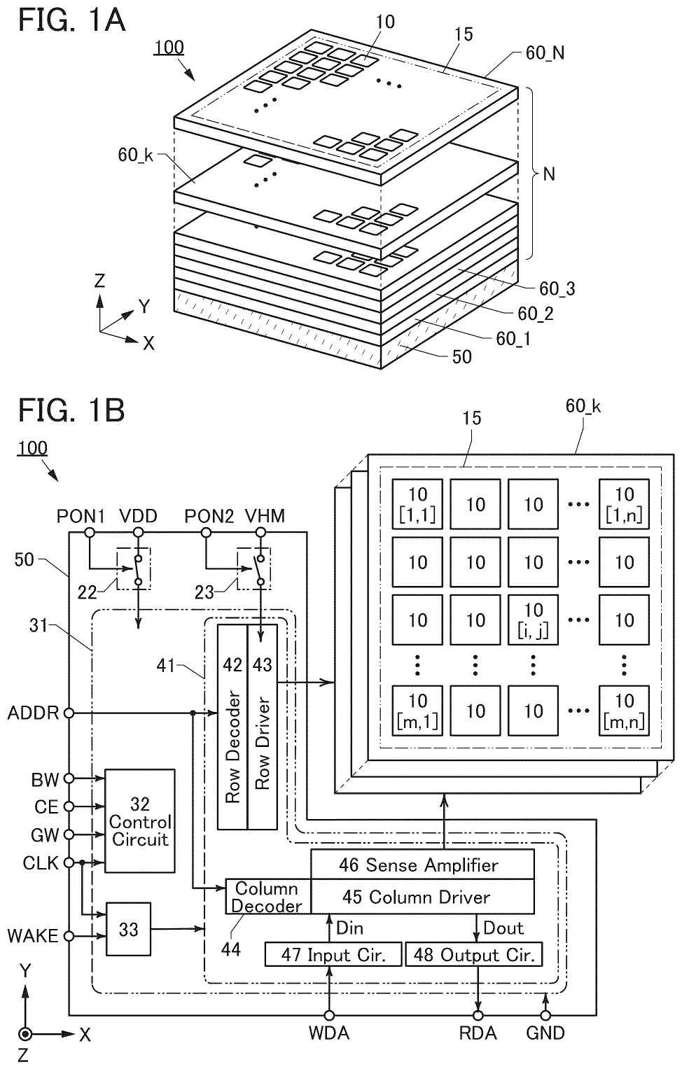

FIG. 1A is a schematic perspective view illustrating a structure example of the storage device 100 of one embodiment of the present invention. FIG. 1B is a block diagram illustrating the structure example of the storage device 100 of one embodiment of the present invention. The storage device 100 includes a driver circuit layer 50 and N memory layers 60 (N is an integer greater than or equal to 1).

The N memory layers 60 are provided over the driver circuit layer 50. Provision of the N memory layers 60 over the driver circuit layer 50 can reduce the area occupied by the storage device 100. Furthermore, the storage capacity per unit area can be increased.

In this embodiment and the like, the first memory layer 60 is referred to as a memory layer 60_1, the second memory layer 60 is referred to as a memory layer 60_2, the third memory layer 60 is referred to as a memory layer 60_3, and the fourth memory layer 60 is referred to as a memory layer 60_4. Furthermore, the k-th memory layer 60 (k is an integer greater than or equal to 1 and less than or equal to N) is referred to as a memory layer 60_k, and the N-th memory layer 60 is referred to as a memory layer 60_N. Note that in this embodiment and the like, the “memory layer 60” is merely stated in some cases when describing a matter related to all the N memory layers 60 or showing a matter common to the N memory layers 60.

### <Structure Example of Driver Circuit Layer 50>

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the storage device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 100. For example, the control circuit performs a logical operation on the signal CE, the signal GW, and the signal BW to determine an operation mode of the storage device 100 (e.g., a writing operation or a reading operation). Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting a wiring WWL (write word line) or a wiring RWL (read word line) specified by the row decoder 42. The column driver 45 has a function of writing data to the memory cells 10, a function of reading data from the memory cells 10, a function of retaining the read data, and the like. The column driver 45 has a function of selecting a wiring WBL (write bit line) or a wiring RBL (read bit line) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the storage device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 100, a high power supply voltage is VDD and a low power supply voltage is GND (ground potential). In addition, VHM is a high power supply voltage used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 1B but can be more than one. In this case, a power switch is provided for each power domain.

### <Structure Example of Driver Circuit Layer 60>

A structure example in which the N memory layers 60 are provided is described. The N memory layers 60 each include a memory array 15. The memory array 15 includes a plurality of memory cells 10. FIG. 1A and FIG. 1B illustrates an example in which the memory array 15 includes the plurality of memory cells 10 arranged in a matrix of m rows and n columns (each of m and n is an integer greater than or equal to 2).

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 1B, the memory cell 10 provided in the first row and the first column is referred to as a memory cell 10[1,1], and the memory cell 10 provided in the first row and the n-th column is referred to as a memory cell 10[1,n]. The memory cell 10 provided in the m-th row and the first column is referred to as a memory cell 10[m,1], and the memory cell 10 provided in the m-th row and the n-th column is referred to as a memory cell 10[m,n]. The memory cell 10 provided in the i-th row and the j-th column (i is an integer greater than or equal to 1 and less than or equal to m and j is an integer greater than or equal to 1 and less than or equal to n) is referred to as a memory cell 10[i,j].

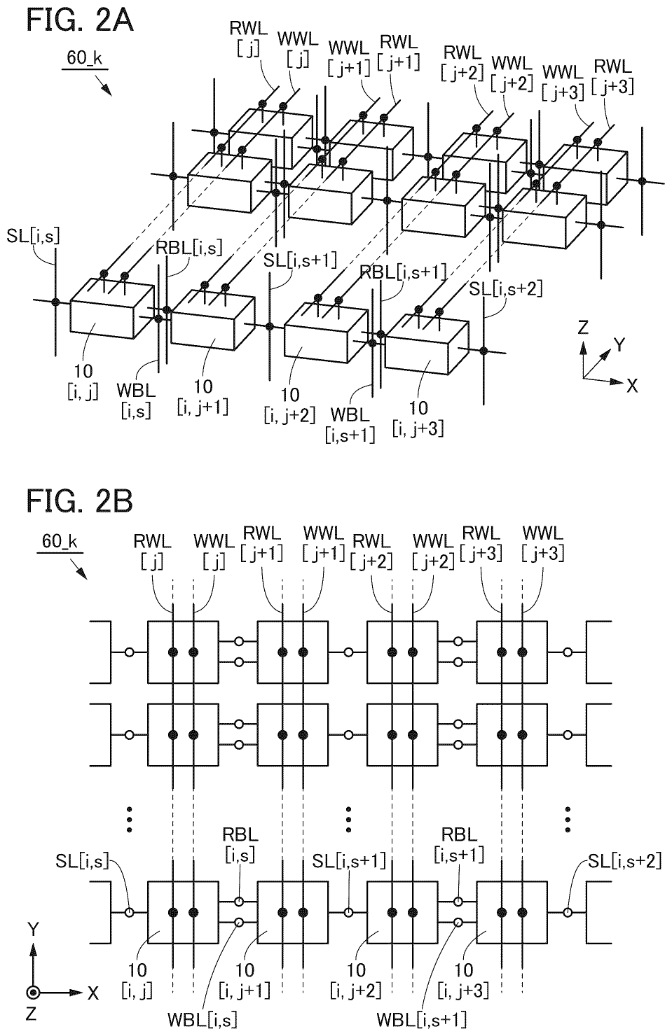

FIG. 2A is an enlarged perspective block diagram of part of the memory layer 60_k. FIG. 2B is a plan view of the portion corresponding to FIG. 2A and seen from the Z direction. Each of the memory layer 60 includes n wirings WWL (write word lines) extending in the Y direction (column direction) and n wirings RWL (read word lines) extending in the Y direction (column direction). In FIGS. 2A and 2B, the wiring WWL provided in the j-th column is referred to as a wiring WWL[j], and the wiring RWL provided in the j-th column is referred to as a wiring RWL[j]. The wiring WWL[j] and the wiring RWL[j] are electrically connected to the memory cell 10 provided in the j-th column. The wiring WWL provided in the j+1-th column is referred to as a wiring WWL[j+1], and the wiring RWL provided in the j+1-th column is referred to as a wiring RWL[j+1]. The wiring WWL provided in the j+2-th column is referred to as a wiring WWL[j+2], and the wiring RWL provided in the j+2-th column is referred to as a wiring RWL[j+2]. The wiring WWL provided in the j+3-th column is referred to as a wiring WWL[j+3], and the wiring RWL provided in the j+3-th column is referred to as a wiring RWL[j+3].

The memory layer 60 includes the wiring WBL (write bit line), the wiring RBL (read bit line), and a wiring SL (selection line). The wirings WBL, the wirings RBL, and the wirings SL extend in the Z direction (perpendicular direction) and are provided in a matrix of m rows and R columns. In FIGS. 2A and 2B, the wiring WBL, the wiring RBL, and the wiring SL provided in the i-th row and the s-th column (s is an integer greater than or equal to 1 and less than or equal to R) are referred to as a wiring WBL[i,s], a wiring RBL[i,s], and a wiring SL [i,s], respectively.

In the memory layer 60_k, one wiring WBL is electrically connected to two memory cells 10. One wiring RBL is electrically connected to two memory cells 10. One wiring SL is electrically connected to two memory cells 10. When one wiring WBL, one wiring RBL, and one wiring SL are shared by two adjacent memory cells 10, the area occupied by the memory array can be reduced. In addition, the integration degree of the memory cell 10 can be increased and the storage capacity of the storage device 100 can be increased.

In FIGS. 2A and 2B, the wiring WBL[i,s] and the wiring RBL[i,s] are electrically connected to the memory cell 10[i,j] and a memory cell 10[i,j+1]. The wiring WBL[i,s+1] and the wiring RBL[i,s+1] are electrically connected to the memory cell 10[i,j+2] and the memory cell [i,j+3]. The wiring WBL[i,s] and the wiring RBL[i,s] are electrically connected to a memory cell 10[i,2×s−1]_k and a memory cell 10[i,2×s]_k.

In FIGS. 2A and 2B, the wiring SL [i,s+1] is electrically connected to the memory cell 10[i,j+1] and the memory cell 10[i,j+2]. Note that the memory cell 10[i,j] is electrically connected to the wiring SL [i,s], and the memory cell 10[i,j+3] is electrically connected to the wiring SL [i,s+2].

The relation between R and n indicating positions of columns can be expressed by Formula 1 or Formula 2 in the case where n is an odd number.

$$R = ( n + 1 ) / 2 \qquad ( Formula 1 )$$

$$n = 2 \times R - 1 \qquad ( Formula 2 )$$

The relation between R and n indicating positions of columns can be expressed by Formula 3 or Formula 4 in the case where n is an even number.

$$R = n / 2 \qquad ( Formula 3 )$$

$$n = 2 \times R \qquad ( Formula 4 )$$

The relation between s and j indicating positions of columns can be expressed by Formula 5 or Formula 6 in the case where j is an odd number.

$$s = ( j + 1 ) / 2 \qquad ( Formula 5 )$$

$$j = 2 \times s - 1 \qquad ( Formula 6 )$$

The relation between s and j indicating positions of columns can be expressed by Formula 7 or Formula 8 in the case where j is an even number.

$$s = j / 2 \qquad ( Formula 7 )$$

$$j = 2 \times s \qquad ( Formula 8 )$$

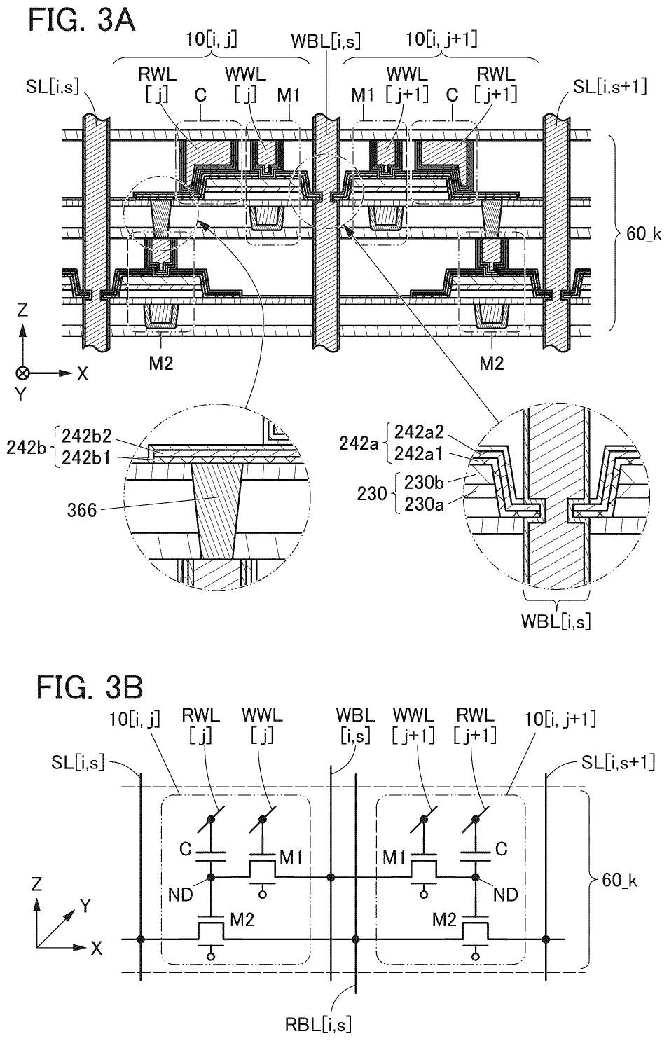

FIG. 3A is a schematic cross-sectional view of the memory cell 10[i,j] and the memory cell 10[i,j+1] in the memory layer 60_k. In FIG. 3B, an example of a circuit structure in FIG. 3A is illustrated. Note that parts of the schematic cross-sectional view are enlarged in FIG. 3A. The wiring RBL[i,s] is provided at a position different from that in the cross section illustrated in FIG. 3A. Thus, the wiring RBL[i,s] is not illustrated in the cross-sectional view in FIG. 3A.

The memory cell 10[i,j] includes a transistor M1, a transistor M2, and a capacitor C. A memory cell composed of two transistors and one capacitor is also referred to as a 2Tr1C memory cell. Thus, the memory cell 10 shown in this embodiment is a 2Tr1C memory cell.

In the memory cell 10[i,j], a gate of the transistor M1 is electrically connected to the wiring WWL[j], and one of a source and a drain of the transistor M1 is electrically connected to the wiring WBL[i,s]. FIG. 3A illustrates a structure example in which part of the wiring WWL[j] functions as the gate of the transistor M1. One electrode of the capacitor C is electrically connected to the wiring RWL[j], and the other electrode is electrically connected to the other of the source and the drain of the transistor M1. FIG. 3A and the like each illustrate a structure example in which part of the wiring RWL[j] functions as the one electrode of the capacitor C. A gate of the transistor M2 is electrically connected to the other electrode of the capacitor C, one of a source and a drain of the transistor M2 is electrically connected to the wiring RBL[i,s], and the other of the source and the drain of the transistor M2 is electrically connected to the wiring SL [i,s].

In the memory cell 10[i,j], a region where the other electrode of the capacitor C, the other of the source and the drain of the transistor M1, and the gate of the transistor M2 are electrically connected and have the same potential constantly is referred to as a node ND.

In the memory cell 10[i,j+1], the gate of the transistor M1 is electrically connected to the wiring WWL[j+1], and the one of the source and the drain of the transistor M1 is electrically connected to the wiring WBL[i,s]. FIG. 3A and the like each illustrate a structure example in which part of the wiring WWL[j+1] functions as the gate of the transistor M1. The one electrode of the capacitor C is electrically connected to the wiring RWL[j+1] and the other electrode thereof is electrically connected to the other of the source and the drain of the transistor M1. FIG. 3A and the like each illustrate a structure example in which part of the wiring RWL[j+1] functions as the one electrode of the capacitor C. The gate of the transistor M2 is electrically connected to the other electrode of the capacitor C, the one of the source and the drain of the transistor M2 is electrically connected to the wiring RBL[i,s], and the other of the source and the drain of the transistor M2 is electrically connected to the wiring SL [i,s+1].

In the memory cell 10[i,j+1], a region where the other electrode of the capacitor C, the other of the source and the drain of the transistor M1, and the gate of the transistor M2 are electrically connected and have the same potential constantly is referred to as the node ND.

As illustrated in FIGS. 3A and 3B, a transistor including a back gate may be used as each of the transistor M1 and the transistor M2. The gate and the back gate are placed such that a channel formation region of a semiconductor is interposed between the gate and the back gate. The gate and the back gate are formed using conductors. The back gate can function like the gate. By changing the potential of the back gate, the threshold voltage of the transistor can be changed. The potential of the back gate may be the same as the potential of the gate or may be a ground potential or a given potential.

In addition, the gate and the back gate are formed using conductors and thus also have a function of preventing an electric field generated outside the transistor from affecting the semiconductor in which a channel is formed (particularly, a function of preventing static electricity). That is, a variation in the electrical characteristics of the transistor due to the influence of an external electric field such as static electricity can be prevented. Moreover, providing the back gate enables a reduction in the amount of change in the threshold voltage of the transistor before and after a BT test.

For example, the use of a transistor including a back gate for the transistor M1 can reduce the influence of an external electric field, allowing the transistor M1 to be maintained in the stable off state. Thus, data written to the node ND can be stably retained for a long time. Providing the back gate stabilizes the operation of the memory cell 10 and can increase the reliability of a storage device including the memory cell 10.

As semiconductor layers in which the channels of the transistor M1 and the transistor M2 are formed, a single crystal semiconductor, a polycrystalline semiconductor, a microcrystalline semiconductor, an amorphous semiconductor, or the like can be used alone or in combination. As a semiconductor material, silicon, germanium, or the like can be used, for example. Alternatively, a compound semiconductor such as silicon germanium, silicon carbide, gallium arsenide, oxide semiconductor, or nitride semiconductor may be used.

As the transistor M1 and the transistor M2, a transistor including an oxide semiconductor, which is a kind of a metal oxide, in a semiconductor layer where a channel is formed (also referred to as an “OS transistor”) is preferably used. An oxide semiconductor has a band gap higher than or equal to 2 eV, and thus has extremely low off-state current. Thus, the power consumption of the memory cells 10 can be reduced. Accordingly, the power consumption of the storage device 100 including the memory cells 10 can be reduced.

A memory cell including an OS transistor can be referred to as an “OS memory”. The storage device 100 including the memory cell can also be referred to as an “OS memory”.

The OS transistor operates stably even in a high-temperature environment and has small fluctuation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current of the OS transistor is unlikely to decrease even in the high-temperature environment. Thus, the OS memory can operate stably and have high reliability even in the high-temperature environment.

In the cross-sectional structure example illustrated in FIG. 3A, a conductor 242a (a conductor 242al and a conductor 242a2) including a region functioning as one of a source electrode and a drain electrode of the transistor M1 extends beyond an oxide 230 (an oxide 230a and an oxide 230b) functioning as the semiconductor layer. Thus, a conductor 242 functions as a wiring. In FIG. 3A, the top surface, a side surface, and the bottom surface of the conductor 242a are partly in electrical contact with the wiring WBL[i,s] extending in the Z direction.

When the wiring WBL[i,s] is in contact with at least one of the top surface, the side surface, and the bottom surface of the conductor 242a, an electrode for connection does not need to be provided separately, so that the area occupied by memory arrays 15 can be reduced. In addition, the integration degree of the memory cell 10 can be increased and the storage capacity of the storage device 100 can be increased. Note that the wiring WBL[i,s] is preferably in contact with two or more of the top surface, the side surface, and the bottom surface of the conductor 242a. When the wiring WBL[i,s] is in contact with the plurality of surfaces of the conductor 242a, the contact resistance between the wiring WBL[i,s] and the conductor 242a can be reduced. A conductor 242b (a conductor 242b1 and a conductor 242b2) including a region functioning as the other of the source and the drain of the transistor M1 extends beyond the oxide 230 (the oxide 230a and the oxide 230b) functioning as the semiconductor layer. In the cross-sectional structure example illustrated in FIG. 3A, a conductor 366 is provided in contact with the bottom surface of the conductor 242b. The conductor 242b and the gate of the transistor M2 are electrically connected to each other through the conductor 366. The conductor 366 functions as a contact plug.

When the conductor 366 is provided in a region overlapping with the conductor 242b and electrically connected to a conductor in a lower layer, the connection distance between the conductors can be shortened. In addition, the number of wirings needed for the structure of the memory cell 10 can be reduced. This can reduce the area occupied by the memory cell 10. Accordingly, the storage capacity and storage density of the storage device can be increased.

Although not illustrated, the one of the source and the drain of the transistor M2 is electrically connected to the wiring RBL[i,s] with a structure similar to that of the one of the source and the drain of the transistor M1. Specifically, the one of the source and the drain of the transistor M2 is electrically connected to the wiring RBL[i,s] through a conductor including a region that functions as one of a source electrode and a drain electrode of the transistor M2. At least one of the top surface, a side surface, and the bottom surface of the conductor is preferably partly in contact with the wiring RBL[i,s].

The other of the source and the drain of the transistor M2 is electrically connected to the wiring SL [i,s] with a structure similar to that of the one of the source and the drain of the transistor M1. Specifically, the other of the source and the drain of the transistor M2 is electrically connected to the wiring SL [i,s] through a conductor including a region that functions as the other of the source electrode and the drain electrode of the transistor M2. At least one of the top surface, a side surface, and the bottom surface of the conductor is preferably in contact with the wiring SL [i,s].

The cross-sectional structure of the memory cell 10 will be described in detail in other embodiments.

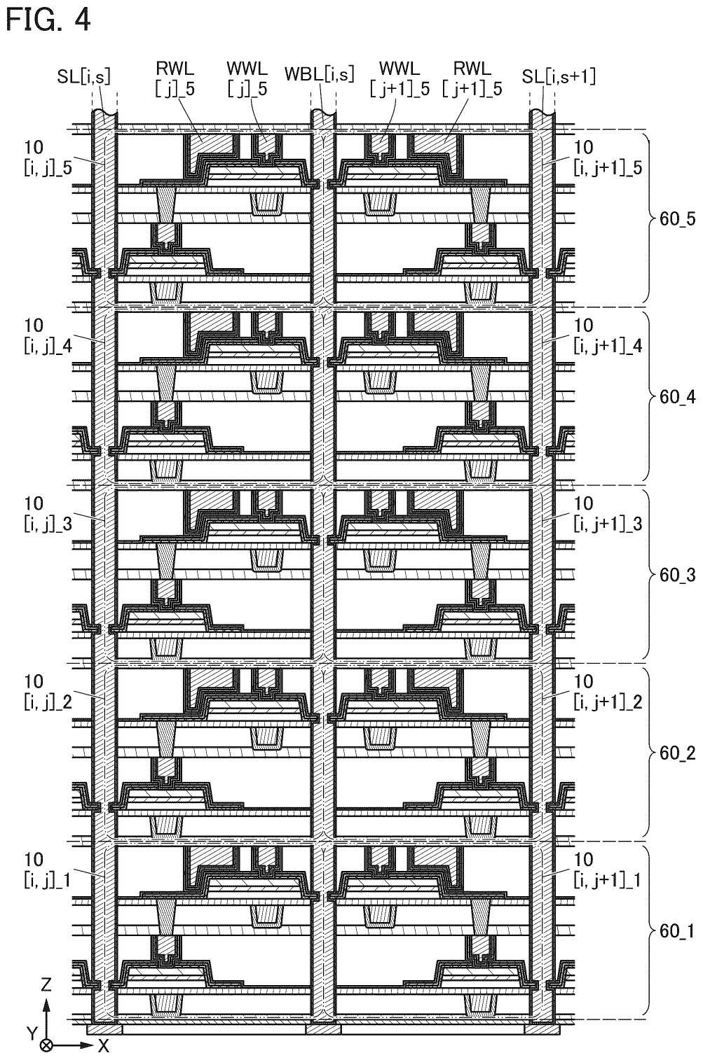

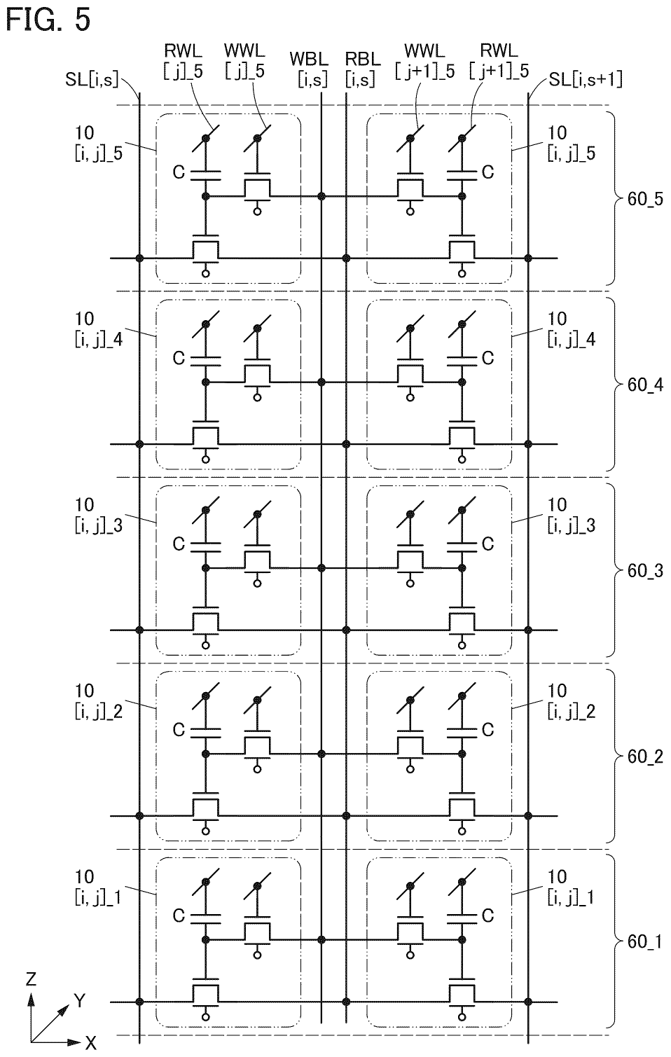

FIG. 4 illustrates a cross-sectional structure example of the memory layer 60 in which the memory layer 60_1 to a memory layer 60_5 are stacked. In FIG. 5, an example of a circuit structure in FIG. 4 is illustrated. In FIG. 4 and FIG. 5, the memory cell 10[i,j] included in each of the memory layer 60_1 to the memory layer 60_5 is referred to as a memory cell 10[i,j]_1 to a memory cell 10[i,j]_5. The wiring WWL[j] included in the memory layer 60_5 is referred to as a wiring WWL[j]_5, and the wiring RWL[j] included in the memory layer 60_5 is referred to as a wiring RWL[j]_5. The wiring WWL[j+1] included in the memory layer 60_5 is referred to as a wiring WWL[j+1]_5, and the wiring RWL[j+1] included in the memory layer 60_5 is referred to as a wiring RWL[j+1]_5.

Although FIG. 4 and FIG. 5 illustrate a structure example in which the five memory layers 60 are stacked, the number of memory layers 60 stacked is not limited to five. By increasing the number of memory layers 60 stacked, the storage capacity of the storage device 100 can be increased without increasing the area occupied by the memory cells 10. Thus, the occupied area per bit is reduced, so that a small storage device with a large storage capacity can be achieved.

### <Operation Example of Memory Cell 10>

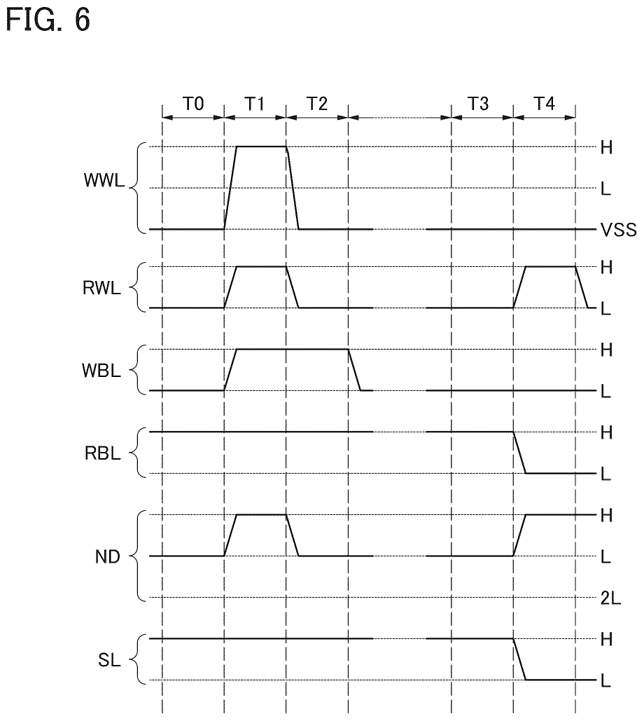

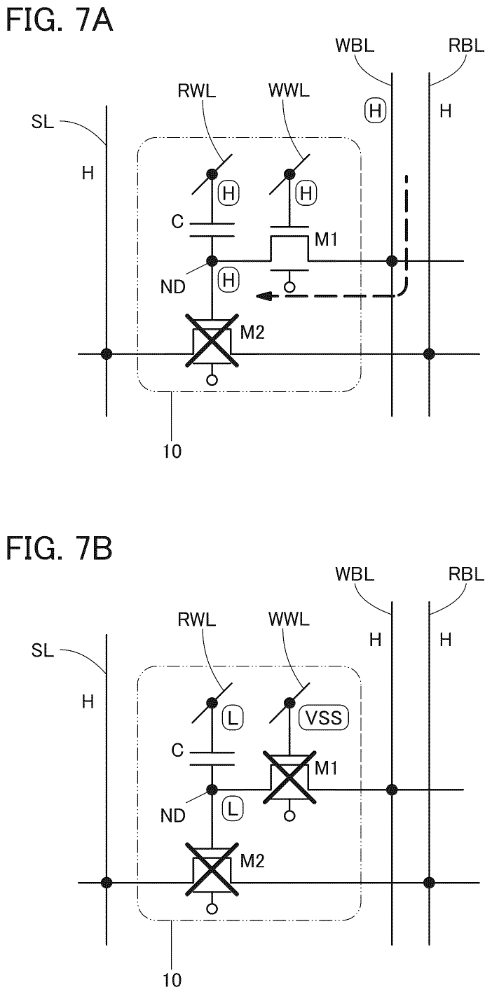

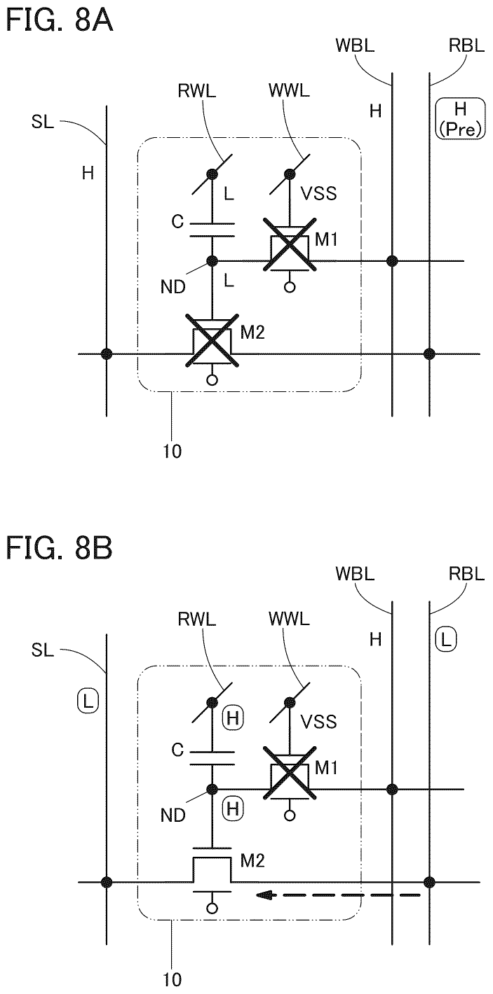

Next, examples of a data writing operation and a data reading operation on the memory cell 10 will be described. In this embodiment, normally-off n-channel transistors are used as the transistor M1 and the transistor M2. FIG. 6 is a timing chart for illustrating the operation examples of the memory cell 10. FIG. 7A, FIG. 7B, FIG. 8A, and FIG. 8B are circuit diagrams for illustrating the operation examples of the memory cell 10.

In the drawings and the like, for showing the potentials of a wiring and an electrode, “H” representing an potential H or “L” representing an potential L is sometimes written near the wiring and the electrode. In addition, enclosed “H” or “L” is sometimes written near a wiring and an electrode whose potential changes. Moreover, in the case where a transistor is in an off state, a symbol “x” is sometimes written on the transistor.

First, in Period TO, the potential of the wiring WWL is VSS, the potentials of the wiring RWL, the wiring WBL, and the node ND are the potential L, and the potentials of the wiring RBL and the wiring SL are the potential H (see FIG. 6). In this embodiment and the like, VSS is a potential lower than or equal to a potential 2L described later. In addition, GND is supplied to the back gates of the transistor M1 and the transistor M2.

### [Data Writing Operation]

In Period T1, the H potential is supplied to the wiring RWL, the wiring WWL, and the wiring WBL (see FIG. 6 and FIG. 7A). Accordingly, the transistor M1 is brought into an on state and the H potential is written to the node ND as data indicating “1”. More accurately, the amount of charge that makes the potential of the node ND be the H potential is supplied to the node ND. Since all of the gate, source, and drain of the transistor M2 have the same potential (H potential), the transistor M2 is brought into an off state.

### [Retaining Operation]

In Period T2, VSS is supplied to the wiring WWL and the potential L is supplied to the wiring RWL. Then, the transistor M1 is brought into an off state and the node ND is brought into a floating state. Thus, data (charge) written to the node ND is retained (see FIG. 6 and FIG. 7B).

At this time, the node ND is in a floating state; thus, the potential of the node ND also changes in accordance with a change in the potential of the wiring RWL. Note that the amount of change in the potential of the node ND depends on the capacity ratio between the capacitor C and the gate capacitance of the transistor M2. For example, in the case where the capacitance value of the capacitor C is sufficiently larger than the gate capacitance of the transistor M2, a potential change that is the same as the potential change in the wiring RWL occurs also at the node ND.

In this embodiment, the capacitance value of the capacitor C is assumed to be sufficiently larger than the gate capacitance of the transistor M2. Thus, when the potential of the wiring RWL changes from the potential H to the potential L, the potential of the node ND also changes from the potential H to the potential L.

Note that in the case where the potential L is supplied to the node ND as data indicating “0” in Period T1, the potential of the node ND in Period T2 becomes a potential (also referred to as “potential 2L”) lower than the potential L by the potential difference between the potential H and the potential L. VSS supplied to the gate of the transistor M1 needs to be a potential lower than or equal to the potential 2L in order to prevent the transistor M1 from being brought into an on state at the time when the potential of the node ND becomes the potential 2L.

As described above, the OS transistor is a transistor having extremely low off-state current. The use of the OS transistor as the transistor M1 enables data written to the node ND to be retained for a long period. Therefore, it becomes unnecessary to refresh the node ND and the power consumption of the memory cell 10 can be reduced. Thus, the power consumption of the storage device 100 can be reduced.

In addition, the OS transistor has a higher drain breakdown voltage than a transistor containing silicon in a semiconductor layer where a channel is formed (also referred to as a Si transistor). Therefore, when the transistor M1 is an OS transistor, the range of potentials retained at the node ND can be widened. Accordingly, multi-level data or analog data can be retained in the node ND.

### [Reading Operation]

In Period T3, the wiring RBL is precharged to the potential H (H (Pre)). That is, the wiring RBL is brought into a floating state while having the potential H (see FIG. 6 and FIG. 8A).

Next, in Period T4, the potential H is supplied to the wiring RWL and the potential L is supplied to the wiring SL (see FIG. 6 and FIG. 8B). When the wiring RWL changes from the potential L to the potential H, the potential of the node ND also changes from the potential L to the potential H. When the potential of the node ND becomes the potential H and the potential of the wiring SL becomes the potential L, the transistor M2 is brought into an on state. When the transistor M2 is brought into an on state, the wiring RBL and the wiring SL are brought into a conduction state, so that the potential of the wiring RBL changes from the H potential to the L potential.

In contrast, in the case where the L potential is written to the node ND as data indicating “0”, the transistor M2 is not brought into an on state even when the L potential is supplied to the wiring SL. Thus, by detecting a change in the potential of the wiring RBL when the L potential is supplied to the wiring SL, data written to the memory cell 10 can be read.

The memory cell 10 using an OS transistor employs a method in which charge is written to the node ND through the OS transistor; hence, high voltage, which a conventional flash memory requires, is unnecessary and a high-speed writing operation is possible. Furthermore, the number of data writing and reading in the memory cell 10 using an OS transistor is substantially unlimited because charge injection and extraction into/from a floating gate or a charge trap layer are not performed. Unlike a flash memory, the memory cell 10 using an OS transistor does not show instability due to an increase of electron trap centers even when a rewriting operation is repeated. The memory cell 10 using an OS transistor is less likely to degrade than a conventional flash memory and can have high reliability.

Unlike a magnetic memory, a resistive random access memory, or the like, the memory cell 10 using an OS transistor has no change in the structure at the atomic level. Thus, the memory cell 10 using an OS transistor has higher rewrite endurance than a magnetic memory and a resistive random access memory.

In the storage device 100 of one embodiment of the present invention, the memory cell and the driver circuit layer 50 are electrically connected to each other through the wiring WBL and the wiring RBL having regions extending in the Z direction. Thus, the lengths of the wiring WBL and the wiring RBL which are led are short, and the wiring resistance and parasitic capacitance thereof are small. Owing to the low wiring resistance and low parasitic capacitance of the wiring WBL and the wiring RBL, the storage device 100 of one embodiment of the present invention has a higher data writing speed and a higher data reading speed.

The structure described in this embodiment can be used in an appropriate combination with any of the structures described in the other embodiments.

### Embodiment 2

In this embodiment, a structure example of a semiconductor device applicable to the memory cell 10 of one embodiment of the present invention will be described with reference to the drawings. The semiconductor device described in this embodiment includes a transistor and a capacitor.

### <Structure Example of Semiconductor Device>

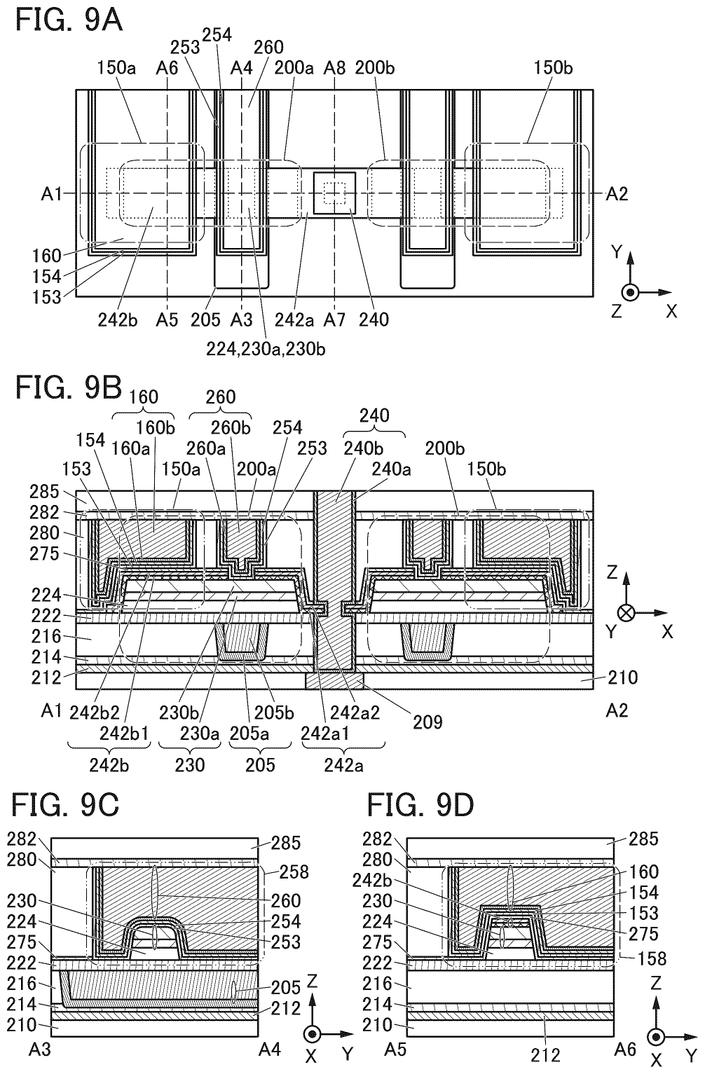

A structure example of a semiconductor device including a transistor and a capacitor is described with reference to FIG. 9. FIG. 9A to FIG. 9D is a top view and a cross-sectional view of a semiconductor device including a transistor 200a, a transistor 200b, a capacitor 150a, and a capacitor 150b.

The transistor 200a or the transistor 200b can be used as the transistor M1 and the transistor M2 described in the above embodiment. The capacitor 150a and the capacitor 150b can be used as the capacitor C described in the above embodiment.

FIG. 9A is a plan view of the semiconductor device. FIG. 9B to FIG. 9D are cross-sectional views of the semiconductor device. Here, FIG. 9B is a cross-sectional view of a portion indicated by the dashed-dotted line A1-A2 in FIG. 9A, is a cross-sectional view of the transistor 200a and the transistor 200b in the channel length direction, and is also a cross-sectional view of the capacitor 150a and the capacitor 150b. FIG. 9C is a cross-sectional view of a portion indicated by the dashed-dotted line A3-A4 in FIG. 9A, and is a cross-sectional view of the transistor 200a in the channel width direction. FIG. 9D is a cross-sectional view of a portion indicated by the dashed-dotted line A5-A6 in FIG. 9A, and is also a cross-sectional view of the transistor 200a and the capacitor 150a in the channel width direction. Note that for clarity of the drawing, some components are not illustrated in the plan view of FIG. 9A.

The X direction illustrated in FIG. 9A is a direction parallel to the channel length direction of the transistor 200a and the channel length direction of the transistor 200b.

The semiconductor device of one embodiment of the present invention includes an insulator 214 over a substrate (not illustrated), the transistor 200a, the transistor 200b, the capacitor 150a, and the capacitor 150b over the insulator 214, an insulator 280 over an insulator 275 provided in the transistor 200a and the transistor 200b, an insulator 282 over the capacitor 150a, the capacitor 150b, and the insulator 280, an insulator 285 over the insulator 282, and a conductor 240 (a conductor 240a and a conductor 240b). The insulator 214, the insulator 280, the insulator 282, and the insulator 285 each function as an interlayer film. As illustrated in FIG. 9B, at least parts of the transistor 200a, the transistor 200b, the capacitor 150a, and the capacitor 150b are placed to be embedded in the insulator 280.

Here, each of the transistor 200a and the transistor 200b includes the oxide 230 functioning as the semiconductor layer, a conductor 260 functioning as a first gate (also referred to as a top gate) electrode, a conductor 205 functioning as a second gate (also referred to as a back gate) electrode, the conductor 242a functioning as one of the source electrode and the drain electrode, and the conductor 242b functioning as the other of the source electrode and the drain electrode. An insulator 253 and an insulator 254 functioning as a first gate insulator are also included. An insulator 222 and an insulator 224 functioning as a second gate insulator are also included. Note that the gate insulator is also referred to as a gate insulating layer or a gate insulating film in some cases.

Note that since the transistor 200a and the transistor 200b have the same structure, in the following description common to the transistor 200a and the transistor 200b, the alphabets added to the reference numerals are omitted and the term “transistor 200” is used in some cases.

A first gate electrode and a first gate insulating film are placed inside an opening 258 formed in the insulator 280 and the insulator 275. That is, the conductor 260, the insulator 254, and the insulator 253 are placed inside the opening 258.

The capacitor 150a and the capacitor 150b each include the conductor 242b functioning as a lower electrode, the insulator 275, an insulator 153, and an insulator 154 each of which functions as a dielectric, and a conductor 160 functioning as an upper electrode. In other words, the capacitor 150a and the capacitor 150b each form a MIM (Metal-Insulator-Metal) capacitor.

Note that the capacitor 150a and the capacitor 150b have the same structure; thus, in the following description common to the capacitor 150a and the capacitor 150b, the alphabets added to the reference numerals are omitted and the term “capacitor 150” is used in some cases.

Part of the upper electrode and the dielectric of a capacitor 150 are placed inside an opening 158 formed in the insulator 280. That is, the conductor 160, the insulator 154, and the insulator 153 are placed inside the opening 158.

The semiconductor device of one embodiment of the present invention includes the conductor 240 (the conductor 240a and the conductor 240b). The conductor 240 includes a region in contact with the conductor 242a and is electrically connected to a transistor 200 to function as a plug.

The semiconductor device of one embodiment of the present invention includes an insulator 210 and a conductor 209 between the substrate (not illustrated) and the insulator 214. The conductor 209 is placed to be embedded in the insulator 210. The conductor 209 includes a region in contact with the conductor 240.

The semiconductor device of one embodiment of the present invention may include an insulator 212 between the insulator 214 and each of the insulator 210 and the conductor 209.

The semiconductor device including the transistor 200 and the capacitor 150 described in this embodiment can be used as a memory cell of the storage device. In this case, the conductor 240 is electrically connected to a sense amplifier in some cases. Here, as illustrated in FIG. 9A, at least part of the capacitor 150 is provided to overlap with the oxide 230 included in the transistor 200. In such a manner, the capacitor 150 can be provided without increasing the area occupied by the capacitor 150 in the plan view, and thus the semiconductor device of this embodiment can be miniaturized or highly integrated.

The semiconductor device described in this embodiment has a line-symmetric structure with respect to the dashed-dotted line A7-A8 illustrated in FIG. 9A. The conductor 242a serves as one of a source electrode and a drain electrode of the transistor 200a and one of a source electrode and a drain electrode of the transistor 200b. Accordingly, when the two transistors, the two capacitors, and the plug are connected as described above, and the plug have the above-described structure, a semiconductor device that can be miniaturized or highly integrated can be provided.

### [Transistor 200]

As illustrated in FIG. 9A to FIG. 9D, the transistor 200 includes an insulator 216 over the insulator 214, the conductor 205 (a conductor 205a and a conductor 205b) placed to be embedded in the insulator 216, the insulator 222 over the insulator 216 and the conductor 205, the insulator 224 over the insulator 222, the oxide 230a over the insulator 224, the oxide 230b over the oxide 230a, the conductor 242a (the conductor 242al and the conductor 242a2) and the conductor 242b (the conductor 242b1 and the conductor 242b2) over the oxide 230b, the insulator 253 over the oxide 230b, an insulator 254 over the insulator 253, the conductor 260 (a conductor 260a and a conductor 260b) positioned over the insulator 254 and overlapping with part of the oxide 230b, and the insulator 275 placed over the insulator 222, the insulator 224, the oxide 230a, the oxide 230b, the conductor 242a, and the conductor 242b.

Note that in this specification and the like, the oxide 230a and the oxide 230b are collectively referred to as the oxide 230 in some cases. The conductor 242a and the conductor 242b are collectively referred to as the conductor 242 in some cases.

The opening 258 reaching the oxide 230b is provided in the insulator 280 and the insulator 275. That is, the opening 258 includes a region overlapping with the oxide 230b. It can be said that the insulator 275 includes an opening overlapping with an opening included in the insulator 280. The insulator 253, the insulator 254, and the conductor 260 are placed inside the opening 258. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor 200. The insulator 254 includes a region in contact with the side surface of the conductor 260 and a region in contact with the bottom surface of the conductor 260. As illustrated in FIG. 9C, the top surface of the insulator 222 is exposed in a region of the opening 258 that does not overlap with the oxide 230.

The oxide 230 preferably includes the oxide 230a placed over the insulator 224 and the oxide 230b placed over the oxide 230a. Including the oxide 230a under the oxide 230b makes it possible to inhibit diffusion of impurities into the oxide 230b from components formed below the oxide 230a.

Although the transistor 200 having a structure in which the oxide 230 is a stack of the two layers, the oxide 230a and the oxide 230b, is described, the present invention is not limited thereto. For example, the oxide 230 may be provided as a single layer of the oxide 230b or as stacked-layer structure of three or more layers, or the oxide 230a and the oxide 230b may each have a stacked-layer structure.

The conductor 260 functions as the first gate electrode and the conductor 205 functions as the second gate electrode. The insulator 253 and the insulator 254 function as the first gate insulator, and the insulator 222 and the insulator 224 function as the second gate insulator. The conductor 242a functions as one of a source electrode and a drain electrode, and the conductor 242b functions as the other of the source electrode and the drain electrode. At least part of a region of the oxide 230 overlapping with the conductor 260 functions as a channel formation region.

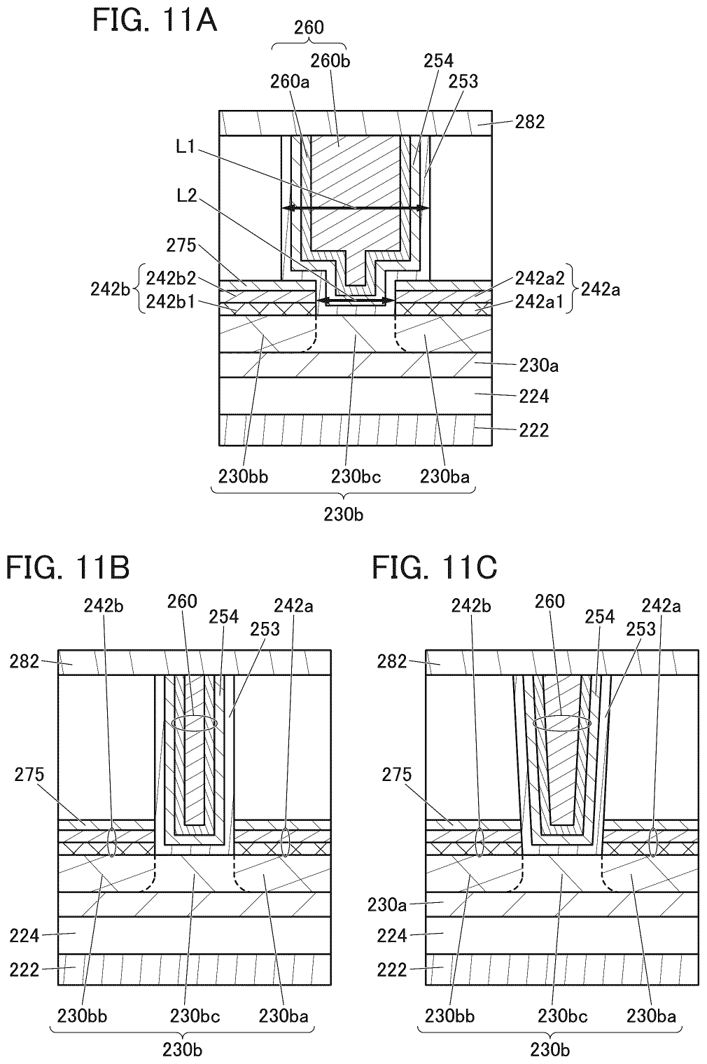

FIG. 11A is an enlarged view of the vicinity of the channel formation region in FIG. 9B. As illustrated in FIG. 11A, in the cross-sectional view of the transistor 200 in the channel length direction, distance L2 between the conductor 242a and the conductor 242b is preferably smaller than the width of the opening 258. Here, the width of the opening 258 corresponds to distance L1 between an interface between the insulator 280 and the insulator 253 on the conductor 242a side and an interface between the insulator 280 and the insulator 253 on the conductor 242b side, which is illustrated in FIG. 11A. Although the details will be described later, in this embodiment, channel etching of the conductor 242a and the conductor 242b is performed after the formation of the opening 258. With such a structure, the distance L2 between the conductor 242a and the conductor 242b can be relatively easily set to be extremely minute (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Since the conductor 260 includes a region having the distance L1 larger than the distance L2, a reduction in the conductivity of the conductor 260 positioned in the region having the distance L1 can be inhibited and the conductor 260 can function as a wiring.

As illustrated in FIG. 11A and FIG. 9C, the opening 258 can be also regarded as having a shape in which part of a structure body including the insulator 224, the oxide 230, the conductor 242, and the insulator 275 protrudes in an opening having the insulator 222 as its bottom surface and the insulator 280 as its side surface. Furthermore, a region of the oxide 230 interposed between the conductor 242a and the conductor 242b can be regarded as being exposed in the structure body including the insulator 224, the oxide 230, the conductor 242, and the insulator 275.

As illustrated in FIG. 11A and FIG. 9C, the insulator 253 is provided in contact with the bottom surface and the inner wall of the opening 258. Thus, the insulator 253 is in contact with at least parts of the top surface of the insulator 222, the side surface of the insulator 224, the side surface of the oxide 230a, the side surface and the top surface of the oxide 230b, the side surfaces of the conductor 242a and the conductor 242b, the side surface of the insulator 275, a side surface of the insulator 280, and the bottom surface of the insulator 254. The insulator 254 and the conductor 260 are stacked over the insulator 253. Thus, the insulator 253, the insulator 254, and the conductor 260 are provided to cover the conductor 242 and the insulator 275 that partly protrude in the opening 258.

The channel formation region is formed in a region of the oxide 230b having the distance L2. Thus, the channel formation region of the transistor 200 is extremely minute. Accordingly, the transistor 200 can have higher on-state current and improved frequency characteristics.

Note that the shape of the opening 258 is not limited to the shape illustrated in FIG. 11A. As illustrated in FIG. 11B, the opening 258 may have a shape in which the distance L1 and the distance L2 are equal. At this time, as illustrated in FIG. 11B, a side surface of the conductor 242a and the side surface of the insulator 275 are substantially aligned with the side surface of the insulator 280. The side surface of the conductor 242b and the side surface of the insulator 275 are substantially aligned with the side surface of the insulator 280. With this structure, the manufacturing process of the semiconductor device can be simplified and the productivity can be improved. A plurality of the transistors 200 can be provided with high density in a small area.

Although FIG. 11B illustrates a structure in which the sidewall of the opening 258 is substantially perpendicular to the top surface of the insulator 222, the present invention is not limited thereto. As illustrated in FIG. 11C, the sidewall of the opening 258 may have a tapered shape. The sidewall of the opening 258 with a tapered shape improves the coverage with the insulator 253 and the like in a later step, so that defects such as a void can be reduced.

Note that in this specification and the like, a tapered shape indicates a shape in which at least part of a side surface of a component is inclined to a substrate surface. For example, it is preferable that a region where an angle formed between the inclined side surface of the component and the substrate surface (bottom surface) (hereinafter, the angle is referred to as a taper angle in some cases) is less than 90° be provided. Note that the side surface of the component and the substrate surface (bottom surface) are not necessarily completely flat and may be substantially flat with a slight curvature or substantially flat with slight unevenness.

As illustrated in FIG. 11A, the oxide 230b includes a region 230bc functioning as the channel formation region of the transistor 200 and a region 230ba and a region 230bb that are provided so as to interpose the region 230bc and function as a source region and a drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than those of the region 230ba and the region 230bb, and thus is a high-resistance region with a low carrier concentration. Thus, the region 230bc can be regarded as being i-type (intrinsic) or substantially i-type.

The region 230ba and the region 230bb functioning as the source region and the drain region are each a low-resistance region with an increased carrier concentration because it includes a large amount of oxygen vacancies or has a high concentration of an impurity such as hydrogen, nitrogen, or a metal element. In other words, the region 230ba and the region 230bb are each an n-type region having a higher carrier concentration and a lower resistance than the region 230bc.

Here, as illustrated in FIG. 11A, the side surfaces of the conductor 242a and the conductor 242b that face each other are preferably substantially perpendicular to the top surface of the oxide 230b. With such a structure, the side end portion of the region 230ba on the region 230bc side that is formed under the conductor 242a can be inhibited from excessively receding from the side end portion of the conductor 242a on the region 230bc side. Similarly, the side end portion of the region 230bb on the region 230bc side that is formed under the conductor 242b can be inhibited from excessively receding from the side end portion of the conductor 242b on the region 230bc side. This can inhibit formation of what is called a Loff region between the region 230ba and the region 230bc and between the region 230bb and the region 230bc. Here, the expression “the side end portion of the region 230ba on the region 230bc side recedes” means that the side end portion of the region 230ba is positioned closer to the conductor 240 than the side surface of the conductor 242a on the region 230bc side is. In addition, the expression “the side end portion of the region 230bb on the region 230bc side recedes” means that the side end portion of the region 230bb is positioned closer to the conductor 160 than the side surface of the conductor 242b on the region 230bc side is.

Accordingly, the frequency characteristics of the transistor 200 can be improved, and the operation speed of the semiconductor device of one embodiment of the present invention can be improved. For example, in the case where the semiconductor device of one embodiment of the present invention is used as a memory cell of a storage device, the writing speed and the reading speed can be improved.

Note that the carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1× 10¹³ cm⁻³, yet still further preferably lower than 1×10¹² cm⁻³. Note that the lower limit of the carrier concentration in the region 230bc functioning as the channel formation region is not particularly limited and can be, for example, 1× 10⁻⁹ cm⁻³.

Between the region 230bc and the region 230ba or the region 230bc and the region 230bb, a region having a carrier concentration that is lower than or substantially equal to the carrier concentrations in the region 230ba and the region 230bb and higher than or substantially equal to the carrier concentration in the region 230bc may be formed. That is, the region functions as a junction region between the region 230bc and the region 230ba or the region 230bc and the region 230bb. The hydrogen concentration in the junction region is lower than or substantially equal to the hydrogen concentrations in the region 230ba and the region 230bb and higher than or substantially equal to the hydrogen concentration in the region 230bc in some cases. The amount of oxygen vacancies in the junction region is smaller than or substantially equal to the amounts of oxygen vacancies in the region 230ba and the region 230bb and larger than or substantially equal to the amount of oxygen vacancies in the region 230bc in some cases.

Although FIG. 11A illustrates an example where the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentration of a metal element and an impurity element such as hydrogen or nitrogen, which is detected in each region, may be not only gradually changed between the regions but also continuously changed in each region. That is, the region closer to the channel formation region preferably has a lower concentration of a metal element and an impurity element such as hydrogen or nitrogen.

In the transistor 200, a metal oxide functioning as a semiconductor (hereinafter, also referred to as an oxide semiconductor) is preferably used for the oxide 230 (the oxide 230a and the oxide 230b) including the channel formation region.

The metal oxide functioning as a semiconductor preferably has a band gap higher than or equal to 2 eV, further preferably higher than or equal to 2.5 eV. With use of a metal oxide having a wide bandgap, the off-state current of the transistor can be reduced.

As the oxide 230, a metal oxide such as indium oxide, gallium oxide, or zinc oxide is preferably used, for example. As the metal oxide 230, a metal oxide containing two or three selected from indium, an element M, and zinc is preferably used, for example. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin. Note that a metal oxide containing indium, the element M, and zinc is referred to as In-M-Zn oxide in some cases.

The oxide 230 preferably has a stacked-layer structure of a plurality of oxide layers with different chemical compositions. For example, the atomic ratio of the element M to a metal element that is a main component of the metal oxide used as the oxide 230a is preferably greater than the atomic ratio of the element M to a metal element that is a main component of the metal oxide used as the oxide 230b. Moreover, the atomic ratio of the element M to In in the metal oxide used as the oxide 230a is preferably greater than the atomic ratio of the element M to In in the metal oxide used as the oxide 230b. With this structure, impurities and oxygen can be inhibited from diffusing into the oxide 230b from the components formed below the oxide 230a.

Furthermore, the atomic ratio of In to the element M in the metal oxide used as the oxide 230b is preferably greater than the atomic ratio of In to the element M in the metal oxide used as the oxide 230a. With this structure, the transistor 200 can have high on-state current and high frequency characteristics.

When the oxide 230a and the oxide 230b contain a common element as the main component besides oxygen, the density of defect states at the interface between the oxide 230a and the oxide 230b can be made low. The density of defect states at the interface between the oxide 230a and the oxide 230b can be made low. Thus, the influence of interface scattering on carrier conduction is small, and the transistor 200 can have high on-state current and excellent frequency characteristics.

Specifically, as the oxide 230a, a metal oxide with a composition of In:M:Zn=1:3:4 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof is used. Note that a composition in the neighborhood includes the range of ±30% of an intended atomic ratio. Gallium is preferably used as the element M. In the case where a single layer of the oxide 230b is provided as the oxide 230, a metal oxide that can be used as the oxide 230a may be used as the oxide 230b.

When the metal oxide is deposited by a sputtering method, the above atomic ratio is not limited to the atomic ratio of the deposited metal oxide and may be the atomic ratio of a sputtering target used for depositing the metal oxide.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in a manufacturing process (what is called thermal budget).

If impurities and oxygen vacancies exist in a region of an oxide semiconductor where a channel is formed, a transistor using the oxide semiconductor may have variable electrical characteristics and poor reliability. In some cases, hydrogen in the vicinity of an oxygen vacancy forms a defect that is the oxygen vacancy into which hydrogen enters (hereinafter sometimes referred to as VoH), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and current flows through the transistor). Thus, impurities, oxygen vacancies, and VoH are preferably reduced as much as possible in the region of the oxide semiconductor where a channel is formed. In other words, it is preferable that the region of the oxide semiconductor where a channel is formed have a reduced carrier concentration and be of an i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor is diffused into a conductor such as the gate electrode, the source electrode, or the drain electrode, the conductor might be oxidized and the conductivity might be impaired, for example, so that electrical characteristics and reliability of the transistor might be adversely affected.

Therefore, the region 230bc functioning as the channel formation region in the oxide semiconductor is preferably an i-type or substantially i-type region with reduced carrier concentration, whereas the region 230ba and the region 230bb functioning as the source region and the drain region are preferably n-type regions with high carrier concentrations. That is, the amounts of oxygen vacancies and VoH in the region 230bc of the oxide semiconductor are preferably reduced. Furthermore, it is preferable that the region 230ba and the region 230bb not be supplied with an excessive amount of oxygen and the amount of VoH in the region 230ba and the region 230bb not be excessively reduced. For example, a reduction in the conductivity of the conductor 260, the conductor 242a, and the conductor 242b, and the like is preferably inhibited. For example, oxidation of the conductor 260, the conductor 242a, and the conductor 242b, and the like is preferably inhibited. Note that hydrogen in an oxide semiconductor can form VoH; thus, the hydrogen concentration needs to be reduced in order to reduce the amount of VoH.

The semiconductor device of this embodiment has a structure in which the hydrogen concentration in the region 230bc is reduced, oxidation of the conductor 242a, the conductor 242b, and the conductor 260 is inhibited, and the hydrogen concentration in the region 230ba and the region 230bb is inhibited from being reduced.

In order to reduce the hydrogen concentration in the region 230bc, the insulator 253 preferably has a function of capturing and fixing hydrogen. As illustrated in FIG. 9C, the insulator 253 includes a region in contact with the region 230bc of the oxide 230b. With this structure, the hydrogen concentration in the region 230bc of the oxide 230b can be reduced. In this manner, VoH in the region 230bc can be reduced, whereby the region 230bc can be an i-type or substantially i-type region.

An example of the insulator having a function of capturing or fixing hydrogen is a metal oxide having an amorphous structure. For example, metal oxide, such as magnesium oxide or oxide containing one or both of aluminum and hafnium, is preferably used. In such a metal oxide having an amorphous structure, an oxygen atom has a dangling bond and sometimes has a property of capturing or fixing hydrogen with the dangling bond. That is, it can be said that the metal oxide having an amorphous structure has high capability of capturing or fixing hydrogen.

The insulator 253 and the insulator 153 that is included in the capacitor 150 are preferably formed using the same insulating film. That is, the insulator 253 and the insulator 153 preferably contain the same material. The insulator 153 functions as a dielectric of the capacitor 150. Thus, a high dielectric constant (high-k) material is preferably used for the insulator 153. At this time, the insulator 253 contains the high-k material. An example of the high-k material is an oxide containing one or both of aluminum and hafnium. With use of the high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, oxide containing one or both of aluminum and hafnium is preferably used, more preferably, oxide containing one or both of aluminum and hafnium and having an amorphous structure is used, and further preferably, hafnium oxide having an amorphous structure is used. In this embodiment, hafnium oxide is used for the insulator 253. In this case, the insulator 253 is an insulator containing at least oxygen and hafnium. The hafnium oxide has an amorphous structure. In that case, the insulator 253 has an amorphous structure.

In order to inhibit oxidation of the conductor 242a, the conductor 242b, and the conductor 260, a barrier insulator against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, a barrier property means a function of capturing and fixing (also referred to as gettering) a targeted substance.

Examples of a barrier insulator against oxygen include oxide containing one or both of aluminum and hafnium, magnesium oxide, gallium oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate). For example, each of the insulator 253, the insulator 254, and the insulator 275 have a single-layer structure or a stacked-layer structure of the barrier insulator against oxygen.

The insulator 253 preferably has a barrier property against oxygen. Note that the insulator 253 is less permeable to oxygen than at least the insulator 280 is. The insulator 253 includes a region in contact with the side surface of the conductor 242a and the side surface of the conductor 242b. When the insulator 253 has a barrier property against oxygen, oxidation of the side surfaces of the conductor 242a and the conductor 242b, which forms oxide films on the side surfaces, can be inhibited. Accordingly, a decrease in the on-state current or field-effect mobility of the transistor 200 can be inhibited.

The insulator 253 is provided in contact with the top surface and the side surface of the oxide 230b, the side surface of the oxide 230a, the side surface of the insulator 224, and the top surface of the insulator 222. When the insulator 253 has a barrier property against oxygen, release of oxygen from the region 230bc of the oxide 230b at the time of performing heat treatment or the like can be inhibited. This can reduce formation of oxygen vacancies in the oxide 230a and the oxide 230b.

Even when an excess amount of oxygen is contained in the insulator 280, the oxygen can be inhibited from being excessively supplied to the oxide 230a and the oxide 230b. Thus, a reduction in on-state current or field-effect mobility of the transistor 200 due to excessive oxidation of the region 230ba and the region 230bb can be inhibited.

Oxide containing one or both of aluminum and hafnium has a barrier property against oxygen and thus can be suitably used for the insulator 253.

The insulator 254 preferably has a barrier property against oxygen. The insulator 254 is provided between the conductor 260 and the region 230bc of the oxide 230 and between the insulator 280 and the conductor 260. Such a structure can inhibit oxygen contained in the region 230bc of the oxide 230 from diffusing into the conductor 260 and thus can inhibit formation of oxygen vacancies in the region 230bc of the oxide 230. Oxygen contained in the oxide 230 and oxygen contained in the insulator 280 can be inhibited from diffusing into the conductor 260 and oxidizing the conductor 260. Note that the insulator 254 is less permeable to oxygen (or less likely to allow diffusion of oxygen) than at least the insulator 280 is. For example, silicon nitride is preferably used for the insulator 254. In this case, the insulator 254 contains at least nitrogen and silicon.

The insulator 275 preferably has a barrier property against oxygen. The insulator 275 is provided between the insulator 280 and the conductor 242a and between the insulator 280 and the conductor 242b. The structure can inhibit diffusion of oxygen contained in the insulator 280 into the conductor 242a and the conductor 242b. As a result, the conductor 242a and the conductor 242b can be inhibited from being oxidized by oxygen contained in the insulator 280, so that an increase in resistivity and a reduction in on-state current can be inhibited. Note that the insulator 275 is less permeable to oxygen than at least the insulator 280 is. For example, silicon nitride is preferably used for the insulator 275. In this case, the insulator 275 contains at least nitrogen and silicon.

In order to inhibit a reduction in the hydrogen concentration in the region 230ba and the region 230bb, a barrier insulator against hydrogen is preferably provided in the vicinity of each of the region 230ba and the region 230bb. In the semiconductor device described in this embodiment, the barrier insulator against hydrogen is, for example, the insulator 275.

Examples of the barrier insulator against hydrogen include oxide such as aluminum oxide, hafnium oxide, and tantalum oxide and nitride such as silicon nitride. For example, the insulator 275 has a single-layer structure or a stacked-layer structure of the barrier insulator against hydrogen.

The insulator 275 preferably has a barrier property against hydrogen. The insulator 275 is placed in contact with the side surface of the region 230ba in the oxide 230b and the side surface of the region 230bb in the oxide 230b. The insulator 275 is placed between the insulator 253 and the side surface of the region 230ba in the oxide 230b and between the insulator 253 and the side surface of the region 230bb in the oxide 230b. When the insulator 275 has a barrier property against hydrogen, capturing and fixing of hydrogen in the region 230ba and the region 230bb by the insulator 253 can be inhibited. Thus, the region 230ba and the region 230bb can each be an n-type region.

With the above structure, the region 230bc functioning as the channel formation region can be an i-type or substantially i-type region, the region 230ba and the region 230bb functioning as the source region and the drain region can be n-type regions, and thus a semiconductor device with favorable electrical characteristics can be provided. The semiconductor device with the above structure can have favorable electrical characteristics even when being miniaturized or highly integrated. For example, even when the distance L2 illustrated in FIG. 11A is less than or equal to 20 nm, less than or equal to 15 nm, less than or equal to 10 nm, or less than or equal to 7 nm, and greater than or equal to 2 nm, greater than or equal to 3 nm, or greater than or equal to 5 nm, favorable electrical characteristics can be obtained.

Furthermore, miniaturization of the transistor 200 can improve high-frequency characteristics. Specifically, a cutoff frequency can be improved. When the gate length is within the above range, the cutoff frequency of the transistor can be greater than or equal to 50 GHz or greater than or equal to 100 GHz at room temperature, for example.

The insulator 253 functions as part of the gate insulator. As illustrated in FIG. 9B, the insulator 253 is provided in contact with the side surface and part of the top surface of the insulator 275 and the side surface of the insulator 280.

Furthermore, the insulator 253 needs to be provided in the opening formed in the insulator 280 and the like, together with the insulator 254 and the conductor 260. The thickness of the insulator 253 is preferably small for miniaturization of the transistor 200. The thickness of the insulator 253 is greater than or equal to 0.1 nm and less than or equal to 5.0 nm, preferably greater than or equal to 0.5 nm and less than or equal to 5.0 nm, further preferably greater than or equal to 1.0 nm and less than or equal to 5.0 nm, still further preferably greater than or equal to 1.0 nm and less than or equal to 3.0 nm. In this case, at least part of the insulator 253 includes a region having the above-described thickness.

To form the insulator 253 having a small thickness as described above, an atomic layer deposition (ALD) method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one has advantages such as deposition of an extremely thin film, deposition on a component with a high aspect ratio, deposition of a film with a small number of defects such as pinholes, deposition with excellent coverage, and low-temperature deposition. Thus, the insulator 253 can be formed on, for example, the side surface of the opening formed in the insulator 280 and the like and the side end portion of the conductor 242 and the like to have a small thickness as described above and to have excellent coverage.

Note that some of precursors used in an ALD method contain carbon or the like. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

The insulator 254 functions as part of the gate insulator. The insulator 254 preferably has a barrier property against hydrogen. This can prevent diffusion of impurities such as hydrogen contained in the conductor 260 into the oxide 230b.

Furthermore, the insulator 254 needs to be provided in the opening formed in the insulator 280 and the like, together with the insulator 253 and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 includes a region having the above-described thickness.

For example, silicon nitride deposited by a PEALD method is used as the insulator 254.

Note that when an insulator having a function of inhibiting passage of oxygen and impurities such as hydrogen, e.g., hafnium oxide, is used as the insulator 253, the insulator 253 can also have the function of the insulator 254. In such a case, the structure without the insulator 254 enables simplification of the manufacturing process and the improvement in productivity of the semiconductor device.

The insulator 275 is provided to cover the insulator 224, the oxide 230a, the oxide 230b, and the conductor 242. Specifically, the insulator 275 includes a region in contact with the side surface of the oxide 230b, the side surface of the conductor 242a, and the side surface of the conductor 242b.

In the opening 258, the insulator 275 overlaps with the conductor 242. With this structure, the physical distance between the conductor 242 and the conductor 260 is increased, so that the parasitic capacitance between the conductor 242 and the conductor 260 can be reduced. Thus, a semiconductor device with favorable electrical characteristics can be provided.

A conductive material that is less likely to be oxidized, a conductive material having a function of inhibiting diffusion (or passage) of oxygen, or the like is preferably used for the conductor 242a, the conductor 242b, and the conductor 260. Examples of the conductive material include a conductive material containing nitrogen and a conductive material containing oxygen. Thus, a decrease in conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 contain at least metal and nitrogen.

One or both of the conductor 242 and the conductor 260 may have a stacked-layer structure. For example, as illustrated in FIG. 9B, the conductor 242a and the conductor 242b may each have a stacked-layer structure of two layers. In this case, for a layer (the conductor 242al and the conductor 242b1) in contact with the oxide 230b, a conductive material that is less likely to be oxidized, a conductive material having a function of inhibiting diffusion (or passage) of oxygen, or the like is preferably used. For example, in the case where the conductor 260 has a stacked-layer structure of the conductor 260a and the conductor 260b as illustrated in FIG. 9B, a conductive material that is less likely to be oxidized, a conductive material having a function of inhibiting diffusion of oxygen, or the like is preferably used for the conductor 260a.

To inhibit a decrease in the conductivity of the conductor 242, oxide having crystallinity, such as a CAAC-OS, is preferably used as the oxide 230b. As the oxide, a metal oxide that can be used as the oxide 230 described above is preferably used. In particular, a metal oxide containing indium, zinc, and one or more selected from gallium, aluminum, and tin is preferably used. The CAAC-OS is an oxide including a crystal, and the c-axis of the crystal is substantially perpendicular to the surface of the oxide or a formation surface. This can inhibit the conductor 242a or the conductor 242b from extracting (gettering) oxygen from the oxide 230b. Furthermore, it is possible to inhibit a reduction in the conductivity of the conductor 242a and the conductor 242b.

In this embodiment, microwave treatment is performed in an atmosphere containing oxygen in a state where the conductor 242a and the conductor 242b covered by the insulator 275 are provided over the oxide 230b and the oxide 230bc is exposed so that oxygen vacancies and VoH in the region 230bc are reduced. Here, the microwave treatment refers to treatment using high-density plasma generated with the use of a high-frequency wave such as a microwave or RF.

A sample in the above state is subjected to microwave treatment in an oxygen-containing atmosphere, whereby the generated oxygen plasma can act on the sample. At this time, the region 230bc is irradiated with the high-frequency wave such as a microwave or RF. By the effect of the oxygen plasma, the high-frequency wave such as a microwave or RF, VOH in the region 230bc can be divided into an oxygen vacancy and hydrogen; the hydrogen can be removed from the region 230bc and the oxygen vacancy can be filled with oxygen. As a result, the hydrogen concentration, oxygen vacancies and VoH of the region 230bc can be reduced to lower the carrier concentration in the region 230bc.

In the microwave treatment in an oxygen-containing atmosphere, the high-frequency wave such as a microwave or RF is blocked by the conductor 242a and the conductor 242b. Thus, the high-frequency wave such as a microwave or RF does not affect the region 230ba and the region 230bb. The insulator 275 covering the conductor 242 can prevent oxidation of the conductor 242 due to oxygen plasma. The insulator 275 and the conductor 242 provided over the region 230ba and the region 230bb prevent a reduction in VoH and supply of an excess amount of oxygen from occurring in the region 230ba and the region 230bb even when the microwave treatment is performed in an oxygen-containing atmosphere; therefore, a decrease in the carrier concentration of the region 230ba and the region 230bb can be prevented.

After an insulating film to be the insulator 253 is formed, microwave treatment is preferably performed in an oxygen-containing atmosphere. By performing the microwave treatment in an oxygen-containing atmosphere through the insulator 253 in such a manner, oxygen can be efficiently implanted into the region 230bc. In addition, the insulator 253 is placed to be in contact with the side surface of the conductor 242 and a surface of the region 230bc, thereby inhibiting oxygen more than necessary from being implanted to the region 230bc and inhibiting the side surface of the conductor 242 from being oxidized.

The oxygen implanted into the region 230bc has any of a variety of forms such as an oxygen atom, an oxygen molecule, and an oxygen radical (an O radical, an atom or a molecule having an unpaired electron, or an ion). Note that the oxygen implanted into the region 230bc has any one or more of the above forms, particularly suitably an oxygen radical. Furthermore, the film quality of the insulator 253 can be improved, leading to higher reliability of the transistor 200.

In the above manner, oxygen vacancies and VoH can be selectively removed from the region 230bc of the oxide semiconductor, whereby the region 230bc can be an i-type or substantially i-type region. Furthermore, supply of an excess amount of oxygen to the region 230ba and the region 230bb functioning as the source region and the drain region can be inhibited and the state of the n-type regions before the microwave treatment is performed can be maintained. As a result, a change in the electrical characteristics of the transistor 200 can be inhibited, and thus a variation in the electrical characteristics of the transistors 200 in the substrate plane can be inhibited.

With the above structure, a semiconductor device with a small variation in transistor characteristics can be provided. Alternatively, a semiconductor device with favorable frequency characteristics can be provided. A semiconductor device with high operating speed can be provided. A semiconductor device with favorable reliability can also be provided. A semiconductor device having favorable electrical characteristics can be provided. A semiconductor device that can be miniaturized or highly integrated can be provided.

As illustrated in FIG. 9C, a curved surface may be provided between the side surface of the oxide 230b and the top surface of the oxide 230b in the cross-sectional view of the transistor 200 in the channel width direction. In other words, an end portion of the side surface and an end portion of the top surface may be curved (hereinafter referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, and further preferably greater than or equal to 2 nm and less than or equal to 10 nm. Such a shape can improve the coverage of the oxide 230b with the insulator 253, the insulator 254, and the conductor 260.

In the manufacturing process of the transistor 200, heat treatment is preferably performed with a surface of the oxide 230 exposed. For example, the heat treatment is performed at higher than or equal to 100° C. and lower than or equal to 600° C., preferably higher than or equal to 350° C. and lower than or equal to 550° C. Note that the heat treatment is performed in a nitrogen gas or inert gas atmosphere, or an atmosphere containing an oxidizing gas at higher than or equal to ppm, higher than or equal to 1%, or higher than or equal to 10%. For example, the heat treatment is preferably performed in an oxygen atmosphere. This can supply oxygen to the oxide 230 to reduce oxygen vacancies. The heat treatment may be performed under reduced pressure. Alternatively, the heat treatment may be performed in such a manner that heat treatment is performed in a nitrogen gas or inert gas atmosphere, and then heat treatment is performed in an atmosphere containing an oxidizing gas at higher than or equal to 10 ppm, higher than or equal to 1%, or higher than or equal to 10% in order to compensate for released oxygen. Alternatively, the heat treatment may be performed in such a manner that heat treatment is performed in an atmosphere containing an oxidizing gas at higher than or equal to 10 ppm, higher than or equal to 1%, or higher than or equal to 10%, and then heat treatment is successively performed in a nitrogen gas or inert gas atmosphere.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of VoH.

As illustrated in FIG. 9C or the like, the insulator 253 is provided in contact with the top surface and the side surface of the oxide 230, whereby indium contained in the oxide 230 is unevenly distributed, in some cases, at the interface between the oxide 230 and the insulator 253 and in its vicinity. Accordingly, the vicinity of the surface of the oxide 230 has an atomic ratio close to that of an indium oxide or that of an In—Zn oxide. Such an increase in the atomic ratio of indium in the vicinity of the surface of the oxide 230, especially the vicinity of a surface of the oxide 230b, can increase the field-effect mobility of the transistor 200.

In addition to the above structure, the semiconductor device of this embodiment preferably has a structure in which hydrogen is inhibited from entering the transistor 200. For example, an insulator having a function of inhibiting diffusion of hydrogen is preferably provided to cover the transistor 200. In the semiconductor device described in this embodiment, the insulator corresponds to, for example, the insulator 212.

As the insulator 212, an insulator having a function of inhibiting diffusion of hydrogen is preferably used. This can inhibit diffusion of hydrogen into the transistor 200 from below the insulator 212. As the insulator 212, an insulator that can be used as the insulator 275 described above is preferably used.

At least one of the insulator 212, the insulator 214, the insulator 282, and the insulator 285 preferably functions as a barrier insulating film, which inhibits diffusion of impurities such as water and hydrogen from the substrate side or above the transistor 200 into the transistor 200. Thus, for at least one of the insulator 212, the insulator 214, the insulator 282, and the insulator 285, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), or a copper atom (an insulating material through which the impurities are less likely to pass) is preferably used. Alternatively, it is preferable to use an insulating material having a function of inhibiting diffusion of oxygen (e.g., at least one of an oxygen atom, an oxygen molecule, and the like) (an insulating material through which the oxygen is less likely to pass).

An insulator having a function of inhibiting diffusion of impurities, such as water and hydrogen, and oxygen is preferably used for the insulator 212, the insulator 214, the insulator 282, and the insulator 285; for example, aluminum oxide, magnesium oxide, hafnium oxide, gallium oxide, indium gallium zinc oxide, silicon nitride, or silicon nitride oxide can be used. For example, silicon nitride or the like, which has a higher hydrogen barrier property, is preferably used for the insulator 212. For example, aluminum oxide, magnesium oxide, or the like, which has a function of capturing or fixing hydrogen, is preferably used for the insulator 214, the insulator 282, and the insulator 285. In this case, impurities such as water and hydrogen can be inhibited from diffusing to the transistor 200 side from the substrate side through the insulator 212 and the insulator 214. Impurities such as water and hydrogen can be inhibited from diffusing to the transistor 200 side from an interlayer insulating film and the like which are placed outside the insulator 285. Alternatively, oxygen contained in the insulator 224 and the like can be inhibited from diffusing to the substrate side through the insulator 212 and the insulator 214. Alternatively, oxygen contained in the insulator 280 and the like can be inhibited from being diffused above the transistor 200 through the insulator 282 and the like. In this manner, the transistor 200 is preferably surrounded by the insulator 212, the insulator 214, the insulator 282, and the insulator 285 which have a function of inhibiting diffusion of oxygen and impurities such as water and hydrogen.

Here, an oxide including an amorphous structure is preferably used for the insulator 212, the insulator 214, the insulator 282, and the insulator 285. For example, a metal oxide such as AlOx (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 200 or provided around the transistor 200, hydrogen contained in the transistor 200 or hydrogen around the transistor 200 can be captured or fixed. In particular, hydrogen contained in the channel formation region of the transistor 200 is preferably captured or fixed. The metal oxide having an amorphous structure is used as the component of the transistor 200 or provided around the transistor 200, whereby the transistor 200 and a semiconductor device which have favorable characteristics and high reliability can be manufactured.

Although the insulator 212, the insulator 214, the insulator 282, and the insulator 285 preferably have an amorphous structure, they may partly include a region with a polycrystalline structure. Alternatively, the insulator 212, the insulator 214, the insulator 282, and the insulator 285 may each have a multilayer structure where a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 282, and the insulator 285 can be deposited by a sputtering method, for example. Since a sputtering method does not need to use a molecule containing hydrogen as a deposition gas, the hydrogen concentrations in the insulator 212, the insulator 214, the insulator 282, and the insulator 285 can be reduced. Note that the deposition method is not limited to a sputtering method, and a chemical vapor deposition (CVD) method, a molecular beam epitaxy (MBE) method, a pulsed laser deposition (PLD) method, an ALD method, or the like can be used as appropriate.

The resistivity of the insulator 212 is preferably low in some cases. For example, by setting the resistivities of the insulator 212 to approximately 1×10¹³ Ωcm, the insulator 212 can sometimes reduce charge up of the conductor 205, the conductor 242, the conductor 260, or the conductor 240 in treatment using plasma or the like in the manufacturing process of a semiconductor device. The resistivities of the insulator 212 is preferably higher than or equal to 1×10¹⁰ Ωcm and lower than or equal to 1×10¹⁵ Ωcm.

The dielectric constants of the insulator 216, the insulator 280, and the insulator 285 are preferably lower than the dielectric constant of the insulator 214. When a material with a low permittivity is used for an interlayer film, parasitic capacitance generated between wirings can be reduced. For the insulator 216, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The conductor 205 is placed to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a depressed portion formed in the conductor 205a. Here, the top surface of the conductor 205b is substantially level with top surfaces of the conductor 205a and the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 205a is formed using a conductive material having a function of reducing diffusion of hydrogen, impurities such as hydrogen contained in the conductor 205b can be prevented from being diffused into the oxide 230 through the insulator 216, the insulator 224, and the like. When the conductor 205a is formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, the conductor 205a is a single layer or stacked layers of the above conductive materials. For example, titanium nitride is used for the conductor 205a.

Moreover, the conductor 205b is preferably formed using a conductive material containing tungsten, copper, or aluminum as its main component. For example, tungsten is used for the conductor 205b.

The conductor 205 sometimes functions as a second gate electrode. In that case, by changing a potential applied to the conductor 205 out of synchronization with and independently of a potential applied to the conductor 260, the threshold voltage (Vth) of the transistor 200 can be controlled. In particular, Vth of the transistor 200 can be higher in the case where a negative potential is applied to the conductor 205, and the off-state current can be reduced. Thus, drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, which makes it possible to reduce the amount of the impurities to be diffused into the oxide 230.

As illustrated in FIG. 9A, the conductor 205 is preferably provided so as to be larger than a region of the oxide 230 that does not overlap with the conductor 242a or the conductor 242b. As illustrated in FIG. 9C, it is particularly preferable that the conductor 205 extend to a region outside end portions of the oxide 230a and the oxide 230b in the channel width direction. That is, the conductor 205 and the conductor 260 preferably overlap with each other with the insulators therebetween on the outer side of the side surface of the oxide 230 in the channel width direction. With this structure, the channel formation region of the oxide 230 can be electrically surrounded by the electric field of the conductor 260 functioning as the first gate electrode and the electric field of the conductor 205 functioning as the second gate electrode.

In this specification and the like, a transistor structure in which a channel formation region is electrically surrounded by at least the electric field of a first gate electrode is referred to as a surrounded channel (S-channel) structure. The S-channel structure disclosed in this specification and the like is different from a Fin-type structure and a planar structure. Meanwhile, the S-channel structure disclosed in this specification and the like can also be regarded as a kind of the Fin-type structure. In this specification and the like, the Fin-type structure refers to a structure in which a gate electrode is placed to cover at least two surfaces (specifically, two surfaces, three surfaces, four surfaces, or the like) of a channel. With the Fin-type structure and the S-channel structure, resistance to a short-channel effect can be enhanced, that is, a transistor in which a short-channel effect is less likely to occur can be provided.

When the transistor 200 has the above-described S-channel structure, the channel formation region can be electrically surrounded. The S-channel structure is a structure with the electrically surrounded channel formation region, and thus is, in a sense, equivalent to a GAA (Gate All Around) structure or an LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can be formed in the entire bulk of the oxide 230. Accordingly, the density of current flowing in the transistor can be improved, and it can be expected to improve the on-state current of the transistor or increase the field-effect mobility of the transistor.

Note that although a transistor with an S-channel structure is exemplified as the transistor 200 illustrated in FIG. 9B, the semiconductor device of one embodiment of the present invention is not limited thereto. For example, a transistor structure that can be employed in one embodiment of the present invention is one or more selected from a planar structure, a Fin-type structure, and a GAA structure.

Furthermore, as illustrated in FIG. 9C, the conductor 205 is extended to function as a wiring as well. However, without limitation to this, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

The insulator 222 and the insulator 224 each function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. Alternatively, an oxide containing hafnium and zirconium, e.g., a hafnium-zirconium oxide is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. A stack of the insulator and any of silicon oxide, silicon oxynitride, and silicon nitride may be used for the insulator 222.

For example, a single layer or stacked layers of an insulator(s) containing what is called a high-k material such as aluminum oxide, hafnium oxide, tantalum oxide, zirconium oxide, or hafnium-zirconium oxide may be used for the insulator 222. As miniaturization and high integration of transistors progress, a problem such as leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr) TiO₃ (BST) may be used for the insulator 222.

Silicon oxide or silicon oxynitride, for example, is used as appropriate for the insulator 224 that is in contact with the oxide 230.

Note that the insulator 222 and the insulator 224 may each have a stacked-layer structure of two or more layers. In that case, without limitation to a stacked-layer structure including the same material, a stacked-layer structure including different materials may be employed. The insulator 224 may be formed into an island shape so as to overlap with the oxide 230a. In this case, the insulator 275 is in contact with the side surface of the insulator 224 and the top surface of the insulator 222. Note that in this specification and the like, the term “island shape” refers to a state where two or more layers formed using the same material in the same step are physically separated from each other.

The conductor 242a and the conductor 242b are provided in contact with the top surface of the oxide 230b. Each of the conductor 242a and the conductor 242b functions as a source electrode or a drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 230b or the like is diffused into the conductor 242a or the conductor 242b in some cases. In particular, when a nitride containing tantalum is used for each of the conductor 242a and the conductor 242b, hydrogen contained in the oxide 230b or the like is likely to be diffused into the conductor 242a or the conductor 242b, and the diffused hydrogen is bonded to nitrogen contained in the conductor 242a or the conductor 242b in some cases. That is, hydrogen contained in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 9D. Accordingly, the conductivity of the conductor 242 is increased, so that the on-state current of the transistor 200 can be increased.

As illustrated in FIG. 9A, the conductor 242a has an opening in a region between the transistor 200a and the transistor 200b. The conductor 240 is placed to overlap with the opening. With this structure, the conductor 242a and the conductor 240 include a region where they are in contact with each other. Thus, the conductor 242a and the conductor 240 are electrically connected to each other.

When heat treatment is performed in the state where the conductor 242a (the conductor 242b) and the oxide 230b are in contact with each other, the sheet resistance of the oxide 230b in a region overlapping with the conductor 242a (the conductor 242b) is decreased in some cases. Furthermore, the carrier concentration is sometimes increased. Thus, the resistance of the oxide 230b in the region overlapping with the conductor 242a (the conductor 242b) can be lowered in a self-aligned manner.

The conductor 242a and the conductor 242b are each preferably formed using a conductive film having compressive stress. This can form distortion extended in the tensile direction (hereinafter, such distortion is sometimes referred to as tensile distortion) in the region 230ba and the region 230bb. When VoH is stably formed in the tensile distortion, the region 230ba and the region 230bb can be stable n-type regions. The compressive stress of the conductor 242a refers to stress for relaxing the compressive shape of the conductor 242a that has a vector in a direction from a center portion to an end portion of the conductor 242a. The same applies to the compressive stress of the conductor 242b.

The level of the compressive stress of the conductor 242a is, for example, preferably higher than or equal to 500 MPa, further preferably higher than or equal to 1000 MPa, still further preferably higher than or equal to 1500 MPa, yet still further preferably higher than or equal to 2000 MPa. The level of the stress of the conductor 242a may be determined from the measured stress of a sample formed by forming a conductive film to be used for the conductor 242a on a substrate. The same applies to the level of the compressive stress of the conductor 242b. An example of a conductor having the above level of compressive stress is a nitride containing tantalum.

Due to the action of the compressive stress of each of the conductor 242a and the conductor 242b, distortion is generated in each of the region 230ba and the region 230bb. The distortion is distortion (tensile distortion) extended in the tensile direction by the action of the compressive stress of each of the conductor 242a and the conductor 242b. In the case where the region 230ba and the region 230bb each have a CAAC structure, the distortion corresponds to extension in the direction perpendicular to the c-axis of the CAAC structure. When the CAAC structure is extended in the direction perpendicular to the c-axis of the CAAC structure, oxygen vacancies are likely to be formed in the distortion. Furthermore, hydrogen is likely to be taken in the distortion, so that VoH is likely to be formed. Thus, oxygen vacancies and VoH are easily formed in the distortion, and they are likely to have a stable structure. Thus, the region 230ba and the region 230bb can be stable n-type regions with high carrier concentrations.

Note that although the distortion formed in the oxide 230b is described above, the present invention is not limited thereto. In some cases, a similar distortion is formed in the oxide 230a.

In the semiconductor device illustrated in FIG. 9A to FIG. 9D, the conductor 242 has a stacked-layer structure of two layers. Specifically, the conductor 242a includes the conductor 242al and the conductor 242a2 over the conductor 242al. Similarly, the conductor 242b includes the conductor 242b1 and the conductor 242b2 over the conductor 242b1. In that case, the conductor 242al and the conductor 242b 1 are placed on the side in contact with the oxide 230b.

Hereinafter, the conductor 242al and the conductor 242b1 are collectively referred to as a lower layer of the conductor 242 in some cases. The conductor 242a2 and the conductor 242b2 are collectively referred to as an upper layer of the conductor 242 in some cases.

The lower layer (the conductor 242al and the conductor 242b1) of the conductor 242 is preferably formed using a conductive material having a property of oxidation resistance. This can inhibit the oxidation of the lower layer of the conductor 242 and a reduction in the conductivity of the conductor 242. Note that the lower layer of the conductor 242 may have such a property that hydrogen is easily absorbed (easily extracted) thereinto. Accordingly, hydrogen in the oxide 230 is diffused into the lower layer of the conductor 242, so that the hydrogen concentration in the oxide 230 can be reduced. As a result, the transistor 200 can have stable electrical characteristics. The lower layer of the conductor 242 preferably has high compressive stress as described above, and preferably has higher compressive stress than the upper layer of the conductor 242. Thus, as described above, the region 230ba and the region 230bb that are in contact with the lower layer of the conductor 242 can be stable n-type regions with a high carrier concentration.

The upper layer of the conductor 242 (the conductor 242a2 and the conductor 242b2) preferably has higher conductivity than the lower layer of the conductor 242 (the conductor 242al and the conductor 242b1). For example, the upper layer of the conductor 242 is thicker than the lower layer of the conductor 242. Note that at least part of the upper layer of the conductor 242 includes a region with higher conductivity than that of the lower layer of the conductor 242. Alternatively, the upper layer of the conductor 242 is preferably formed using a conductive material with lower resistivity than that of the lower layer of the conductor 242. As a result, a semiconductor device with reduced wiring delay can be manufactured.

Note that the upper layer of the conductor 242 may have such a property that hydrogen is easily absorbed. Accordingly, hydrogen absorbed by the lower layer of the conductor 242 is also diffused into the upper layer of the conductor 242, so that the hydrogen concentration in the oxide 230 can be further reduced. As a result, the transistor 200 can have stable electrical characteristics.

In the case where the conductor 242 has a stacked-layer structure of two layers, one or more selected from constituent elements, chemical composition, and film formation conditions may be different between the lower layer of the conductor 242 and the upper layer of the conductor 242.

For example, tantalum nitride or titanium nitride can be used for the lower layer of the conductor 242 (the conductor 242al and the conductor 242b1), and tungsten can be used for the upper layer of the conductor 242 (the conductor 242a2 and the conductor 242b2). In this case, the conductor 242al and the conductor 242b1 each contain tantalum or titanium and nitrogen. With this structure, oxidation of the lower layer of the conductor 242 and a decrease in conductivity of the conductor 242 can be inhibited. With this structure, the conductor 242a2 can be surrounded by the insulator 275 having a barrier property against oxygen and the conductor 242al having a property of being less likely to be oxidized, and the conductor 242b2 can be surrounded by the insulator 275 having a barrier property against oxygen and the conductor 242b1 having a property of being less likely to be oxidized. Thus, a semiconductor device in which oxidation of the conductor 242a2 and the conductor 242b2 and wiring delay are inhibited can be manufactured.

Alternatively, for example, a nitride containing tantalum (e.g., tantalum nitride) may be used for the lower layer of the conductor 242, and a nitride containing titanium (e.g., titanium nitride) may be used for the upper layer of the conductor 242. Titanium nitride can have higher conductivity than tantalum nitride; thus, the conductivity of the upper layer of the conductor 242 can be higher than that of the lower layer of the conductor 242. Thus, the contact resistance between the conductor 242 and the conductor 240 provided in contact with the top surface of the conductor 242 can be reduced, so that a semiconductor device with reduced wiring delay can be manufactured.

Although an example where the lower layer of the conductor 242 and the upper layer of the conductor 242 are formed using different conductive materials is described above, the present invention is not limited thereto.

For the lower layer of the conductor 242 and the upper layer of the conductor 242, conductive materials containing the same constituent elements and having different chemical compositions are preferably used. In this case, the lower layer of the conductor 242 and the upper layer of the conductor 242 can be formed successively without being exposed to an atmospheric environment. By the formation without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum at an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, a nitride containing tantalum at an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. As a result, a semiconductor device with reduced wiring delay can be manufactured.

Note that the boundary between the upper layer and the lower layer of the conductor 242 is difficult to clearly detect in some cases. In the case where a nitride containing tantalum is used for the conductor 242, the tantalum concentration and the nitrogen concentration detected in each layer may gradually change within each layer and may also change continuously (or in a gradation manner) in a region between the upper layer and the lower layer. That is, the atomic ratio of nitrogen to tantalum is preferably higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

Although the conductor 242 has a stacked-layer structure of two layers in the transistor 200, the present invention is not limited thereto. For example, the conductor 242 may have a single-layer structure or a stacked-layer structure of three or more layers. In the case where a component has a stacked-layer structure, layers may be distinguished by ordinal numbers given corresponding to the formation order.

The top surface of the conductor 260 is placed to be substantially aligned with the uppermost portion of the insulator 254, the uppermost portion of the insulator 253, and the top surface of the insulator 280.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. Although the conductor 260 is illustrated to have a two-layer structure of the conductor 260a and the conductor 260b in FIG. 9B and FIG. 9C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation of the conductor 260b due to oxygen diffused from the insulator 280 side. As the conductive material having a function of inhibiting diffusion of oxygen, for example, titanium, titanium nitride, tantalum, tantalum nitride, ruthenium, or ruthenium oxide is preferably used.

The conductor 260 is formed to fill the opening 258 provided to extend in the channel width direction and the conductor 260 is also provided to extend in the channel width direction. Thus, when the plurality of transistors 200 are provided, the conductor 260 can function as a wiring. In this case, the insulator 253 and the insulator 254 are also provided to extend together with the conductor 260.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening 258 formed in the insulator 280 and the like. The formation of the conductor 260 in this manner allows the conductor 260 to be placed properly in a region between the conductor 242a and the conductor 242b without alignment.

As illustrated in FIG. 9C, in the channel width direction of the transistor 200, with reference to the bottom surface of the insulator 222, the level of the bottom surface of the conductor 260 in a region where the conductor 260 and the oxide 230b do not overlap is preferably lower than the level of the bottom surface of the oxide 230b. When the conductor 260 functioning as the gate electrode covers the side surface and the top surface of the channel formation region of the oxide 230b with the insulator 253 and the like therebetween, the electric field of the conductor 260 is likely to act on the entire channel formation region of the oxide 230b. Thus, the on-state current of the transistor 200 can be increased, and the frequency characteristics of the transistor 200 can be improved. With a reference to the bottom surface of the insulator 222, the difference between the level of the bottom surface of the conductor 260 in a region where the conductor 260 do not overlap with the oxide 230a or the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening is formed in the region where the insulator 253, the insulator 254, and the conductor 260 are provided. In addition, the top surface of the insulator 280 may be planarized.

The insulator 280 functioning as an interlayer film preferably has a low permittivity. When a material with a low permittivity is used for an interlayer film, the parasitic capacitance generated between wirings can be reduced. The insulator 280 is preferably provided using a material similar to that for the insulator 216, for example. In particular, silicon oxide and silicon oxynitride, which are thermally stable, are preferable. In particular, preferred materials are silicon oxide, silicon oxynitride, and porous silicon oxide with which a region containing oxygen to be released by heating can be easily formed.

The concentration of impurities such as water and hydrogen in the insulator 280 is preferably reduced. Oxide containing silicon such as silicon oxide, silicon oxynitride, or the like is used as appropriate for the insulator 280, for example.

The insulator 282 is placed to be in contact with at least parts of the top surfaces of the conductor 260, the insulator 253, the insulator 254, and the insulator 280.

The insulator 282 preferably functions as a barrier insulating film that inhibits impurities such as water and hydrogen from being diffused into the insulator 280 from above and preferably has a function of capturing impurities such as hydrogen. The insulator 282 preferably functions as a barrier insulating film that inhibits passage of oxygen. For the insulator 282, a metal oxide having an amorphous structure, for example, an insulator such as aluminum oxide is used. In this case, the insulator 282 contains at least oxygen and aluminum. When the insulator 282 having a function of capturing impurities such as hydrogen is provided in contact with the insulator 280, impurities such as hydrogen contained in the insulator 280 and the like can be captured. It is preferable to use, in particular, aluminum oxide having an amorphous structure for the insulator 282, because hydrogen can be captured or fixed more effectively in some cases. Accordingly, the transistor 200 and a semiconductor device which have favorable characteristics and high reliability can be manufactured.

As the insulator 282, aluminum oxide is preferably deposited by a sputtering method, further preferably, aluminum oxide is deposited by a pulsed DC sputtering method using an aluminum target in an atmosphere containing an oxygen gas. The use of the pulsed DC sputtering method can achieve more uniform thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 is smaller as the RF power is lower, and the amount of oxygen is easily saturated even when the insulator 282 has a small thickness. Moreover, the amount of oxygen implanted into the layer below the insulator 282 is larger as the RF power is higher.

The RF power is higher than or equal to 0 W/cm² and lower than or equal to 1.86 W/cm², for example. In other words, an appropriate amount of oxygen for the transistor characteristics can be changed and implanted by RF power used for the formation of the insulator 282. Accordingly, an appropriate amount of oxygen for improving the reliability of the transistor can be implanted.

The RF frequency is preferably higher than or equal to 10 MHz. The typical frequency is 13.56 MHz. The higher the RF frequency is, the less damage the substrate gets.

Although FIG. 9A to FIG. 9D and the like illustrate a single-layer structure of the insulator 282, the present invention is not limited thereto, and a stacked-layer structure of two or more layers may be employed. The insulator 282 may have a stacked-layer structure of two layers, for example.

An upper layer and a lower layer of the insulator 282 are preferably formed using the same material by different methods. For example, in the case where aluminum oxide is deposited as the insulator 282 by a pulsed DC sputtering method using an aluminum target in an atmosphere containing an oxygen gas, the RF power applied to the substrate in depositing the lower layer of the insulator 282 is preferably different from the RF power applied to the substrate in depositing the upper layer of the insulator 282, and further preferably, the RF power applied to the substrate in depositing the lower layer of the insulator 282 is lower than the RF power applied to the substrate in depositing the upper layer of the insulator 282. Specifically, the RF power applied to the substrate in the deposition of the lower layer of the insulator 282 is higher than or equal to 0 W/cm² and lower than or equal to 0.62 W/cm², and the RF power applied to the substrate in the deposition of the upper layer of the insulator 282 is lower than or equal to 1.86 W/cm². More specifically, the RF power applied to the substrate in the deposition of the lower layer of the insulator 282 is 0 W/cm², and the RF power applied to the substrate in the deposition of the upper layer of the insulator 282 is 0.31 W/cm². With this structure, the insulator 282 can have an amorphous structure, and the amount of oxygen supplied to the insulator 280 can be controlled.

Note that the RF power applied to the substrate in depositing the lower layer of the insulator 282 may be higher than the RF power applied to the substrate in depositing the upper layer of the insulator 282. Specifically, the RF power applied to the substrate in the deposition of the lower layer of the insulator 282 is lower than or equal to 1.86 W/cm², and the RF power applied to the substrate in the deposition of the upper layer of the insulator 282 is higher than or equal to 0 W/cm² and lower than or equal to 0.62 W/cm². More specifically, the RF power applied to the substrate in the deposition of the lower layer of the insulator 282 is 1.86 W/cm², and the RF power applied to the substrate in the deposition of the upper layer of the insulator 282 is 0.62 W/cm². With this structure, the amount of oxygen supplied to the insulator 280 can be increased.

The thickness of the lower layer of the insulator 282 is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With this structure, the lower layer of the insulator 282 can have an amorphous structure regardless of the value of RF power. When the lower layer of the insulator 282 has an amorphous structure, the upper layer of the insulator 282 is likely to have an amorphous structure and the insulator 282 can have an amorphous structure.

Although the lower layer of the insulator 282 and the upper layer of the insulator 282 form a stacked-layer structure including the same material, the present invention is not limited thereto. The lower layer of the insulator 282 and the upper layer of the insulator 282 may form a stacked-layer structure including different materials.

The above is the description of the transistor 200.

### [Capacitor 150]

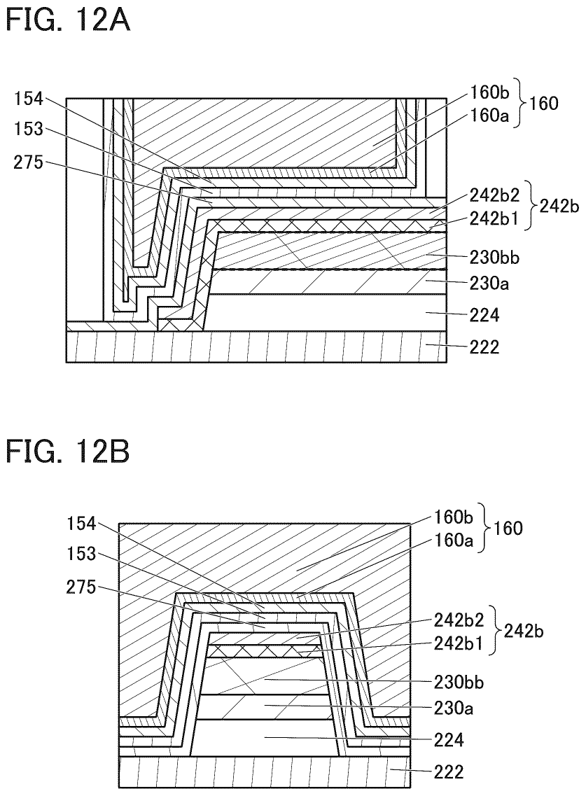

FIG. 12A is an enlarged view of the capacitor 150 and the vicinity thereof in FIG. 9B, and FIG. 12B is an enlarged view of the capacitor 150 and the vicinity thereof in FIG. 9D.

The capacitor 150 includes the conductor 242b, the insulator 275, the insulator 153, the insulator 154, and the conductor 160 (a conductor 160a and a conductor 160b). The conductor 242b functions as one of a pair of electrodes of the capacitor 150 (also referred to as a lower electrode), the conductor 160 functions as the other of the pair of electrodes of the capacitor 150 (also referred to as an upper electrode), and the insulator 275, the insulator 153, and the insulator 154 function as the dielectrics of the capacitor 150.

The insulator 153, the insulator 154, the conductor 160a, and the conductor 160b are placed inside the opening 158 provided in the insulator 280. The insulator 153 is provided over the insulator 275, the insulator 154 is provided over the insulator 153, the conductor 160a is provided over the insulator 154, and the conductor 160b is provided over the conductor 160a.

Although details will be described later, the insulator 153, the insulator 154, the conductor 160a, and the conductor 160b included in the capacitor 150 can be formed using the same materials and the same steps as the insulator 253, the insulator 254, the conductor 260a, and the conductor 260b included in the transistor 200. Thus, the insulator 153 preferably contains the same insulating material as the insulator 253; for the details, the description of the insulator 253 can be referred to. The insulator 154 preferably contains the same insulating material as the insulator 254; for the details, the description of the insulator 254 can be referred to. The conductor 160a preferably contains the same conductive material as the conductor 260a; for the details, the description of the conductor 260a can be referred to. The conductor 160b preferably contains the same conductive material as the conductor 260b; for the details, the description of the conductor 260b can be referred to.

When the insulator 153, the insulator 154, the conductor 160a, and the conductor 160b are formed using the same material and the same step as the insulator 253, the insulator 254, the conductor 260a, and the conductor 260b, the number of steps in the manufacturing process of the semiconductor device can be reduced.

The opening 158 is provided in the insulator 280 to reach the insulator 275. That is, the opening 158 includes a region overlapping with the insulator 275.

As illustrated in FIG. 9A, a region where the conductor 160 and the conductor 242b intersect with each other in the opening 158 functions as the capacitor 150 in the plan view. The region includes a region overlapping with the oxide 230b functioning as the transistor 200. That is, the capacitor 150 can be provided without an excessive increase in the area occupied by the capacitor 150 as compared to the area occupied by the transistor 200. In that case, miniaturization and high integration of the semiconductor device can be achieved. For example, in the case where the semiconductor device of one embodiment of the present invention is used as a memory cell of a storage device, the storage capacity per unit area can be increased.

The conductor 242b can serve as the lower electrode of the capacitor 150 and the other of the source electrode and the drain electrode of the transistor 200. Thus, the manufacturing process of the capacitor 150 can also serve as part of the manufacturing process of the transistor 200; therefore, the productivity of the semiconductor device can be improved.

As illustrated in FIG. 12A, an end portion of the conductor 242b on the capacitor 150 side is preferably positioned outward from the end portion of the oxide 230. In other words, the conductor 242b covers the side surface of the oxide 230 on the capacitor 150 side. Since the conductor 242b functions as the one of the pair of electrodes of the capacitor 150, the area where the pair of electrodes of the capacitor 150 overlap with each other can be increased with this structure. Thus, the capacitance value of the capacitor 150 can be increased.

As illustrated in FIG. 12A and FIG. 12B, the opening 158 can be also regarded as having a shape in which part of a structure body including the insulator 224, the oxide 230, the conductor 242, and the insulator 275 protrudes in an opening having the insulator 222 as its bottom surface and the insulator 280 as its side surface. Unlike the opening 258, the top surface of the oxide 230b is covered with the conductor 242b and the insulator 275 in the opening 158; thus, the top surface of the oxide 230b is not exposed in the opening 158.

As illustrated in FIG. 12A and FIG. 12B, the insulator 153 is provided in contact with the bottom surface and the inner wall of the opening 158. Thus, the insulator 153 is in contact with the top surface of the insulator 275 and a side surface of the insulator 280. The insulator 154 is provided over the insulator 153 in contact with the top surface of the insulator 153, and the conductor 160 is provided in contact with the top surface of the insulator 154. Thus, the insulator 153, the insulator 154, and the conductor 160 are provided to cover the conductor 242b and the insulator 275 that partly protrude in the opening 158.

When the capacitor 150 has the above-described structure, as illustrated in FIG. 12A and FIG. 12B, the conductor 160 is provided to face each of the top surface of the conductor 242b, the side surface of the conductor 242b on the side opposite to the conductor 242a side (the side surface on the A1 side in the capacitor 150a and the side surface of on the A2 side in the capacitor 150b), the side surface of the conductor 242b on the A5 side, and the side surface of the conductor 242b on the A6 side with the insulator 153 and the insulator 154 therebetween. Accordingly, the capacitor 150 can be formed on the four planes of the conductor 242b; thus, the electrostatic capacitance per unit area of the capacitor 150 can be increased. Thus, miniaturization and high integration of the semiconductor device can be achieved.

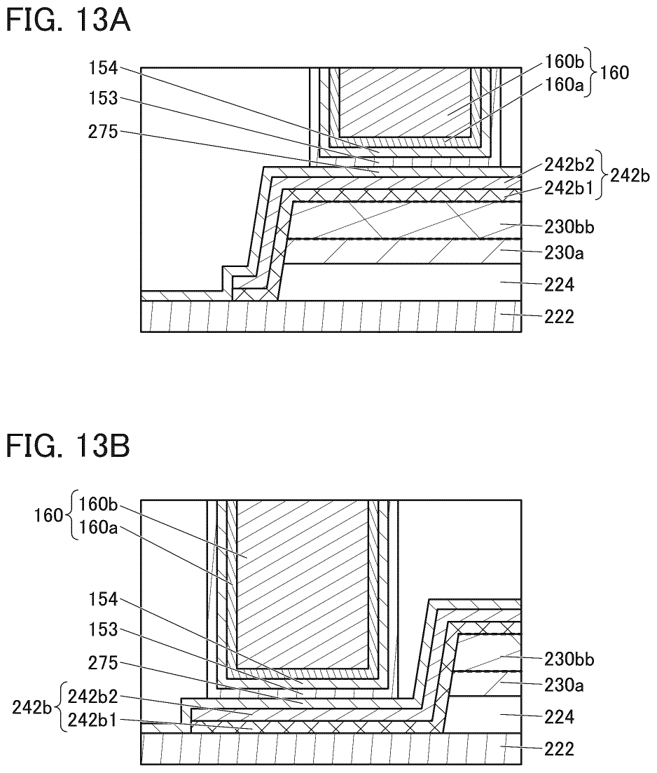

Note that the capacitor 150 may have a shape illustrated in FIG. 13A by optimizing a material used for an insulator functioning as the dielectric, the thickness of the insulator 280, or the like. Specifically, the side surface of the opening 158 on the side opposite to the conductor 242a side (the side surface on the A1 side in the capacitor 150a and the side surface on the A2 side in the capacitor 150b) may overlap with the oxide 230b. The conductor 160 may be provided to face each of the top surface of the conductor 242b, the side surface of the conductor 242b on the A5 side, and the side surface of the conductor 242b on the A6 side with the insulator 153 and the insulator 154 therebetween. In this case, the capacitor 150 can be formed in the above three planes of the conductor 242b. Alternatively, the capacitor 150 may have a shape illustrated in FIG. 13B, for example. Specifically, the opening 158 may be provided in a region not overlapping with the oxide 230b.

Although FIG. 12A, FIG. 13A, and FIG. 13B illustrates a structure in which the sidewall of the opening 158 is substantially perpendicular to the top surface of the insulator 222, the present invention is not limited thereto. The sidewall of the opening 158 may have a tapered shape. Although the details will be described later, the opening 258 and the opening 158 are formed in the same step. For example, as illustrated in FIG. 11C, in the case where the sidewall of the opening 258 has a tapered shape, the sidewall of the opening 158 also has a tapered shape. With such a tapered sidewall of the opening 158, the coverage with the insulator 153 and the like can be improved in a later step, so that the defects such as a void can be reduced.

The conductor 160 is formed to fill the opening 158 provided to extend in the channel width direction of the transistor 200 and the conductor 160 is also provided to extend in the channel width direction of the transistor 200. Thus, when the plurality of transistors 200 and the capacitors 150 are provided, the conductor 160 can function as a wiring. In this case, the insulator 153 and the insulator 154 are also provided to extend together with the conductor 160.

The insulator 275, the insulator 153, and the insulator 154 function as the dielectrics of the capacitor 150. A region of the insulator 153 that functions as the dielectric of the capacitor 150 is interposed between the insulator 275 and the insulator 154.

The region 230bb of the oxide 230b is a low-resistance region. Thus, the region 230bb of the oxide 230b can function as the lower electrode of the capacitor 150 in some cases. At this time, the area where the pair of electrodes of the capacitor 150 overlap with each other can be increased. Thus, the capacitance value of the capacitor 150 can be increased.

The above is the description of the capacitor 150.

The conductor 240 is provided in contact with the inner wall of the opening in the insulator 285, the insulator 282, the insulator 280, the insulator 275, the conductor 242a, the insulator 222, the insulator 216, the insulator 214, and the insulator 212. The conductor 240 includes a region in contact with the top surface of the conductor 209.

Here, the conductor 240 functions as a plug or a wiring for electrically connecting the transistor 200 to a circuit element such as a switch, a transistor, a capacitor, an inductor, a resistor, or a diode, a wiring, an electrode, or a terminal.

The conductor 240 preferably has a stacked-layer structure of the conductor 240a and the conductor 240b. For example, as illustrated in FIG. 9B, the conductor 240 can have a structure in which the conductor 240a is provided in contact with the inner wall of the opening and the conductor 240b is provided inside the conductor 240a. That is, the conductor 240a is placed in the vicinity of the insulator 285, the insulator 282, the insulator 280, the insulator 275, the conductor 242a, the insulator 222, the insulator 216, the insulator 214, and the insulator 212.

A conductive material having a function of inhibiting passage of impurities such as water or hydrogen is preferably used for the conductor 240a. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 282 can be inhibited from entering the oxide 230 through the conductor 240.

The conductor 240 also functions as a wiring and thus is preferably formed using a conductor having high conductivity. For example, a conductive material containing tungsten, copper, or aluminum as its main component can be used for the conductor 240b.

Although the transistor 200 having a structure in which the conductor 240 is a stack of the conductor 240a and the conductor 240b is illustrated, the present invention is not limited thereto. For example, the conductor 240 may have a single-layer structure or a stacked-layer structure of three or more layers. In the case where a component has a stacked-layer structure, layers may be distinguished by ordinal numbers given corresponding to the formation order. Although not illustrated in FIG. 9B, the level of the top surface of the conductor 240 is higher than that of the top surface of the insulator 285 in some cases.

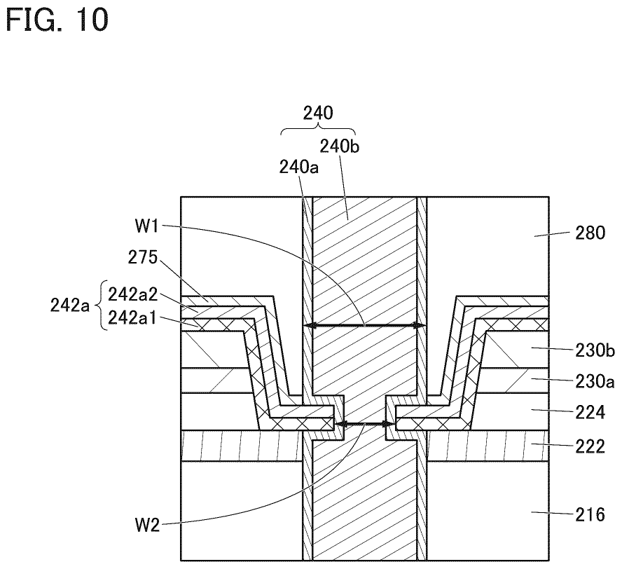

FIG. 10 is an enlarged view of a region where the conductor 240 and the conductor 242a are in contact with each other and vicinity thereof. As illustrated in FIG. 10, in the A1-A2 direction, the conductor 240 includes a region having a width W1 and a region having a width W2. The width W1 corresponds to, for example, the distance between the interface between the insulator 280 and the conductor 240a on the transistor 200a side and the interface between the insulator 280 and the conductor 240a on the transistor 200b side. The width W2 corresponds to the width of the opening included in the conductor 242a.

As illustrated in FIG. 10, the width W1 is preferably larger than the width W2. In this structure, the conductor 240 is in contact with at least part of the top surface and part of the side surface of the conductor 242a. Accordingly, the area of the region where the conductor 240 and the conductor 242a are in contact with each other can be increased. Note that in this specification and the like, contact between the conductor 240 and the conductor 242a is referred to as top-side contact in some cases. As illustrated in FIG. 10, the conductor 240 may be in contact with part of the bottom surface of the conductor 242a. With such a structure, the area of the region where the conductor 240 and the conductor 242a are in contact with each other can be further increased.

The conductor 209 functions as part of a circuit element such as a switch, a transistor, a capacitor, an inductor, a resistor, or a diode, a wiring, an electrode, or a terminal.

The insulator 210 functions as an interlayer film. As the insulator 210, an insulator that can be used as the insulator 214, the insulator 216, or the like described above is preferably used.

### <Component Materials of Semiconductor Device>

Component materials that can be used for the semiconductor device are described below.

### <<Substrate>

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate containing silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as leakage current may arise because of a thinner gate insulator. When a high-k material is used for the insulator functioning as a gate insulator, the voltage at the time of the operation of the transistor can be reduced while the physical thickness is maintained. By contrast, when a material with a low relative permittivity is used for the insulator functioning as an interlayer film, parasitic capacitance generated between wirings can be reduced. Thus, a material is preferably selected depending on the function of an insulator.

Examples of the insulator with a high relative permittivity include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor using a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### <<Metal Oxide>

The oxide 230 is preferably formed using a metal oxide functioning as a semiconductor (an oxide semiconductor). A metal oxide that can be used as the oxide 230 of the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also collectively referred to as a metal oxide in some cases. A metal oxide containing nitrogen may be called a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structures>

Amorphous (including a completely amorphous structure), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method. The XRD spectrum obtained by GIXD measurement may be hereinafter simply referred to as an XRD spectrum.

For example, the XRD spectrum of the quartz glass substrate shows a peak with a substantially bilaterally symmetrical shape. Meanwhile, the peak of the XRD spectrum of an In—Ga—Zn oxide film having a crystal structure has a bilaterally asymmetrical shape. The asymmetrical peak of the XRD spectrum clearly shows the existence of crystals in the film or the substrate. In other words, the crystal structure of the film or the substrate cannot be regarded as amorphous unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass is in an amorphous state. Furthermore, not a halo pattern but a spot-like pattern is observed in the diffraction pattern of the In—Ga—Zn oxide film formed at room temperature. Thus, it is suggested that the In—Ga—Zn oxide formed at room temperature is in an intermediate state, which is neither a single crystal nor polycrystal nor an amorphous state, and it cannot be concluded that the In—Ga—Zn oxide is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the CAAC-OS and the nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS includes a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter less than 10 nm). In the case where the crystal region is formed of one fine crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Thus, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than that in the composition of the CAC-OS film. Moreover, the second region has [Ga] higher than that in the composition of the CAC-OS film. For example, the first region has higher [In] and lower [Ga] than the second region. Moreover, the second region has higher [Ga] and lower [In] than the first region.

Specifically, the first region is a region containing indium oxide, indium zinc oxide, or the like as its main component. The second region is a region containing gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure in which metal elements are unevenly distributed.

The CAC-OS can be formed by a sputtering method under a condition where a substrate is not heated, for example. In the case of forming the CAC-OS by a sputtering method, one or more selected from an inert gas (typically, argon), an oxygen gas, and a nitrogen gas may be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has a higher conductivity than the second region. In other words, when carriers flow through the first region, the conductivity of a metal oxide is exhibited. Accordingly, when the first regions are distributed in a metal oxide like a cloud, high field-effect mobility (u) can be achieved.

Meanwhile, the second region has a higher insulating property than the first region. In other words, when the second regions are distributed in a metal oxide, leakage current can be inhibited.

Thus, in the case where a CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Ion), a high field-effect mobility (u), and an excellent switching operation can be achieved.

A transistor including the CAC-OS has high reliability. Thus, the CAC-OS is most suitable for a variety of semiconductor devices such as display apparatuses.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states are reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that impurities in an oxide semiconductor refer to, for example, elements other than the main components of an oxide semiconductor. For example, an element with a concentration lower than 0.1 atomic % can be regarded as an impurity.

### <Impurities>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the oxide semiconductor is set lower than or equal to 2×10¹⁸ atoms/cm³, preferably lower than or equal to 2× 10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

### <<Other Semiconductor Materials>

A semiconductor material that can be used for the oxide 230 is not limited to the above metal oxides. A semiconductor material that has a band gap (a semiconductor material that is not a zero-gap semiconductor) may be used for the oxide 230. For example, a single element semiconductor such as silicon, a compound semiconductor such as gallium arsenide, or a layered substance functioning as a semiconductor (also referred to as an atomic layer material or a two-dimensional material) is preferably used as a semiconductor material. In particular, a layered substance functioning as a semiconductor is suitably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having high on-state current can be provided.

Examples of the layered substance include graphene, silicene, and chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

For the oxide 230, a transition metal chalcogenide functioning as a semiconductor is preferably used, for example. Specific examples of the transition metal chalcogenide which can be used for the oxide 230 include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). When the transition metal chalcogenide is used for the oxide 230, a semiconductor device with high on-state current can be provided.

### <Modification Example of Semiconductor Device>

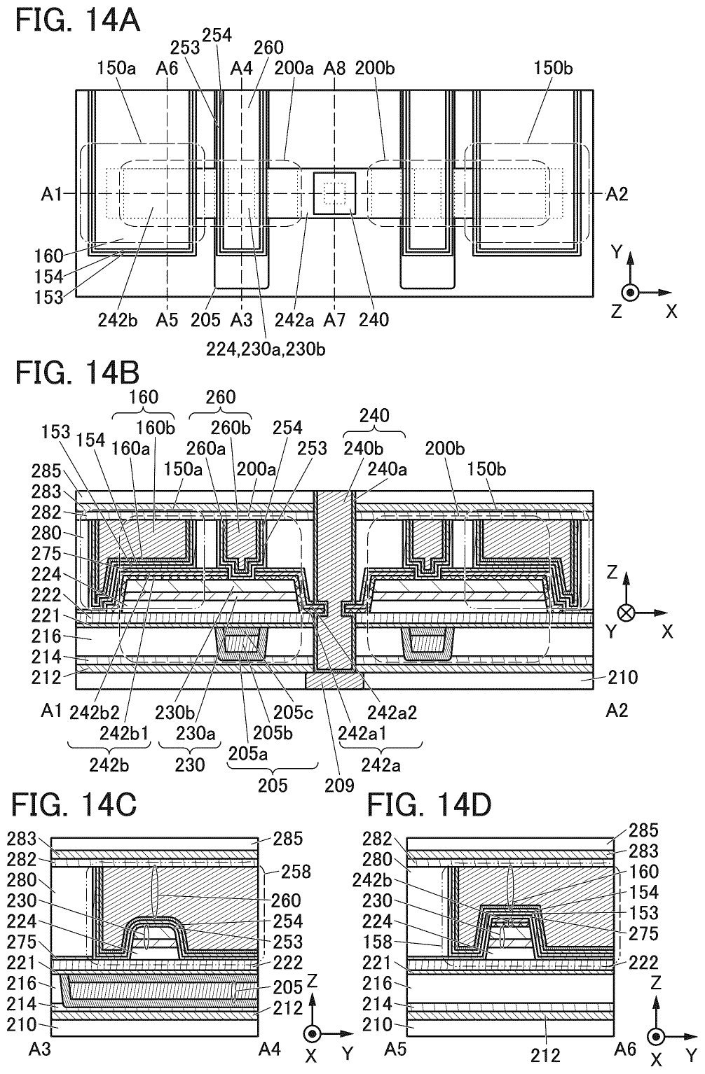

An example of the semiconductor device of one embodiment of the present invention will be described below with reference to FIG. 14A to FIG. 14D.

FIG. 14A illustrates a top view of the semiconductor device. FIG. 14B is a cross-sectional view corresponding to a portion indicated by the dashed-dotted line A1-A2 in FIG. 14A. FIG. 14C is a cross-sectional view corresponding to a portion indicated by the dashed-dotted line A3-A4 in FIG. 14A. FIG. 14D is a cross-sectional view corresponding to a portion indicated by the dashed-dotted line A5-A6 in FIG. 14A. Note that for clarity of the drawing, some components are not illustrated in the top view of FIG. 14A.

In the semiconductor devices illustrated in FIG. 14A to FIG. 14D, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

The semiconductor device illustrated in FIG. 14A to FIG. 14D is a modification example of the semiconductor device illustrated in FIG. 9A to FIG. 9D. The semiconductor device illustrated in FIG. 14A to FIG. 14D is different from the semiconductor device illustrated in FIG. 9A to FIG. 9D in including an insulator 283 and an insulator 221.

The insulator 283 is provided between the insulator 282 and the insulator 285. As the insulator 283, an insulator having a function of inhibiting diffusion of hydrogen is preferably used. This can inhibit diffusion of hydrogen into the transistor 200 from above the insulator 283. Note that as the insulator 283, an insulator that can be used as the insulator 275 described above is used. For example, silicon nitride deposited by a sputtering method is used for the insulator 283. When the insulator 283 is deposited by a sputtering method, a high-density silicon nitride film can be formed. As the insulator 283, silicon nitride deposited by a PEALD method or a CVD method may be stacked over silicon nitride deposited by a sputtering method.

The insulator 282, which has a function of capturing impurities such as hydrogen, is provided in contact with the insulator 280 in a region interposed between the insulator 212 and the insulator 283, whereby impurities such as hydrogen contained in the insulator 280 and the like can be captured and the amount of hydrogen in the region can be constant. It is preferable to use, in particular, aluminum oxide having an amorphous structure for the insulator 282, because hydrogen can be captured or fixed more effectively in some cases. Accordingly, the transistor 200 and a semiconductor device which have favorable characteristics and high reliability can be manufactured.

The transistor 200 illustrated in FIG. 14A to FIG. 14D has a structure in which the insulator 283 is provided as a single layer; however, the present invention is not limited thereto. The insulator 283 may have a stacked-layer structure of two or more layers, for example.

For example, in the case where the insulator 283 has a stacked-layer structure of two layers, a silicon nitride may be deposited by a sputtering method as a lower layer of the insulator 283 and a silicon nitride may be deposited by an ALD method as an upper layer of the insulator 283. By using a sputtering method, which does not need to use a molecule containing hydrogen as a deposition gas, the hydrogen concentration in the lower layer of the insulator 282 can be reduced. Furthermore, in the case where a pinhole, disconnection, or the like is formed in the film deposited by a sputtering method, a portion overlapping with the pinhole, the disconnection, or the like can be filled with the film deposited by an ALD method with excellent coverage.

Note that in the case where the insulator 283 has a stacked-layer structure of two layers, part of the top surface of the upper layer of the insulator 283 is removed in some cases. The boundary between the upper layer and the lower layer of the insulator 283 is difficult to clearly detect in some cases.

The insulator 221 is provided between the insulator 222 and each of the insulator 216 and the conductor 205. The insulator 221 preferably has a function of inhibiting diffusion of hydrogen. This can inhibit diffusion of hydrogen into the transistor 200 from below the insulator 221. Note that the insulator 221 can also have a function of the insulator 212. In such a case, the structure without the insulator 212 enables simplification of the manufacturing process and the improvement in productivity of the semiconductor device.

Note that as the insulator 221, an insulator that can be used as the insulator 275 described above is preferably used. For the insulator 221, a silicon nitride deposited by an ALD method (especially a PEALD method) is preferably used, for example. When deposited by an ALD method, the insulator 221 can have favorable coverage even when unevenness is formed by the insulator 216 and the conductor 205. This can inhibit formation of a pinhole, disconnection, or the like in the insulator 222 formed over the insulator 221.

An insulator having a function of inhibiting diffusion of hydrogen may be provided between the insulator 222 and the insulator 224. This can inhibit diffusion of hydrogen into the transistor 200 from below the insulator.

As illustrated in FIG. 14B and FIG. 14C, the conductor 205 may have a stacked-layer structure of three layers, the conductor 205a, the conductor 205b, and a conductor 205c. The conductor 205c is provided in contact with the top surface of the conductor 205b. The side surface of the conductor 205c is in contact with the conductor 205a. In addition, the top surface of the conductor 205c and the uppermost portion of the conductor 205a may be substantially aligned with each other.

Like the conductor 205a, a conductive material having a function of reducing diffusion of hydrogen is preferably used for the conductor 205c. Thus, the conductor 205b can be surrounded by the conductor 205a and the conductor 205c, so that impurities such as hydrogen contained in the conductor 205b can be prevented from diffusing into the oxide 230 through the insulator 216, the insulator 224, and the like. When the conductor 205a and the conductor 205c are formed using a conductive material having a function of inhibiting diffusion of oxygen, the conductivity of the conductor 205b can be inhibited from being lowered because of oxidation.

A change in electrical characteristics of an OS transistor such as the transistor 200 due to exposure to radiation is small, i.e., an OS transistor has high tolerance to radiation; thus, an OS transistor can be suitably used even in an environment where radiation might enter. For example, OS transistors can be suitably used in outer space. Specifically, OS transistors can be used as transistors in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in the semiconductor devices provided in remote control robots that are controlled remotely in demolishment of a reactor facility, taking out of a nuclear fuel or a fuel debris, a field investigation on a space with a large amount of radioactive substance, and the like.

According to one embodiment of the present invention, a novel transistor can be provided. Alternatively, a semiconductor device that can be miniaturized or highly integrated can be provided. Alternatively, a semiconductor device with favorable frequency characteristics can be provided. A semiconductor device with high operating speed can be provided. A semiconductor device with a small variation in transistor characteristics can be provided. Alternatively, a semiconductor device having favorable electrical characteristics can be provided. Alternatively, a semiconductor device having favorable reliability can be provided. Alternatively, a semiconductor device with high on-state current can be provided. Alternatively, a semiconductor device with a high field-effect mobility can be provided. Alternatively, a semiconductor device with low power consumption can be provided.

The structure described in this embodiment can be used in an appropriate combination with any of the structures described in the other embodiments.

### Embodiment 3

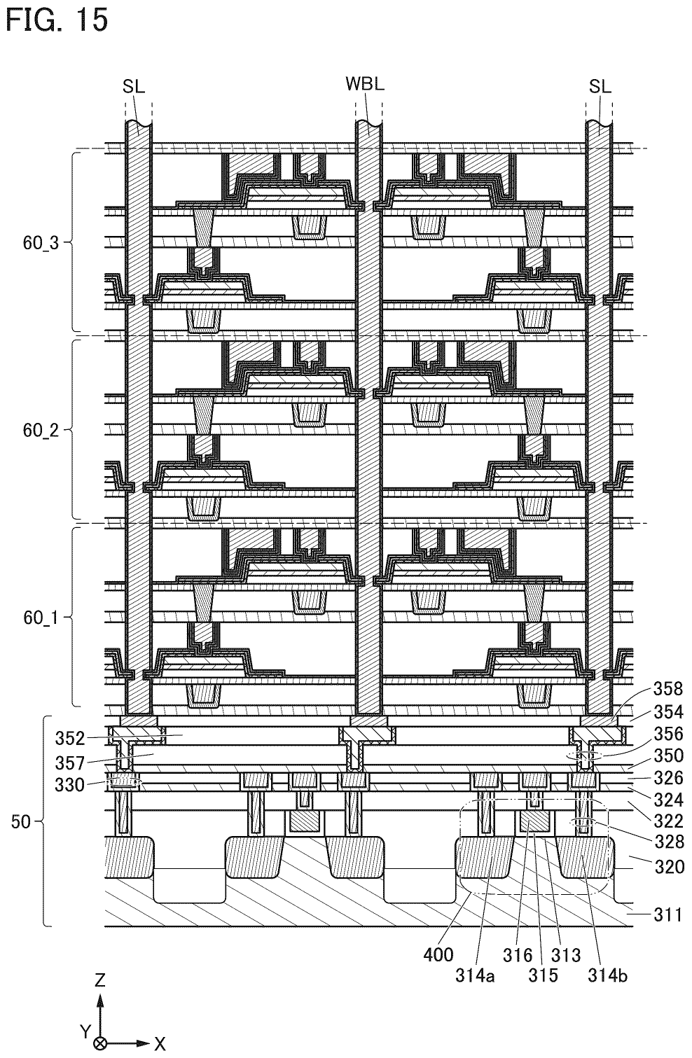

FIG. 15 illustrates a cross-sectional structure example of the storage device 100 of one embodiment of the present invention. The storage device 100 illustrated in FIG. 15 includes a plurality of memory layers 60 above the driver circuit layer 50. To reduce repeated description, the description of the memory layer 60 in this embodiment is omitted.

FIG. 15 illustrates a transistor 400 included in the driver circuit layer 50 as an example. The transistor 400 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 400 may be a p-channel transistor or an n-channel transistor. As the substrate 311, a single crystal silicon substrate can be used, for example.

Here, in the transistor 400 illustrated in FIG. 15, the semiconductor region 313 (part of the substrate 311) where a channel is formed has a protruding shape. In addition, the conductor 316 is provided to cover the side surface and the top surface of the semiconductor region 313 with the insulator 315 therebetween. Note that a material adjusting the work function may be used for the conductor 316. Such the transistor 400 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon on Insulator) substrate.

Note that the transistor 400 illustrated in FIG. 15 is an example and the structure is not limited thereto; an appropriate transistor can be used in accordance with a circuit structure or a driving method.

Wiring layers provided with an interlayer film, a wiring, a plug, and the like may be provided between the components. A plurality of wiring layers can be provided in accordance with design. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 400 as interlayer films. A conductor 328 and the like are embedded in the insulator 320 and the insulator 322. A conductor 330 and the like are embedded in the insulator 324 and the insulator 326. Note that the conductor 328 and the conductor 330 function as a contact plug or a wiring.

The insulators functioning as interlayer films may also function as planarization films that cover uneven shapes therebelow. For example, the top surface of the insulator 322 may be planarized by planarization treatment using a chemical mechanical polishing (CMP) method or the like to improve the planarity.

A wiring layer may be provided over the insulator 326 and the conductor 330. For example, in FIG. 15, an insulator 350, an insulator 357, an insulator 352, and an insulator 354 are stacked sequentially over the insulator 326 and the conductor 330. A conductor 356 is formed in the insulator 350, the insulator 357, and the insulator 352. The conductor 356 functions as a contact plug or a wiring.

The insulator 354 is provided over the insulator 352 and the conductor 356. A conductor 358 is embedded in the insulator 354. The conductor 358 functions as a contact plug or a wiring. For example, the wiring SL and the transistor 400 are electrically connected to each other through the conductor 358, the conductor 356, the conductor 330, and the like.

This embodiment can be combined as appropriate with any of the other embodiments and the like described in this specification.

### Embodiment 4

In this embodiment, examples of electronic components in which the storage device or the like described in the above embodiment is incorporated will be described.

### <Electronic Component>

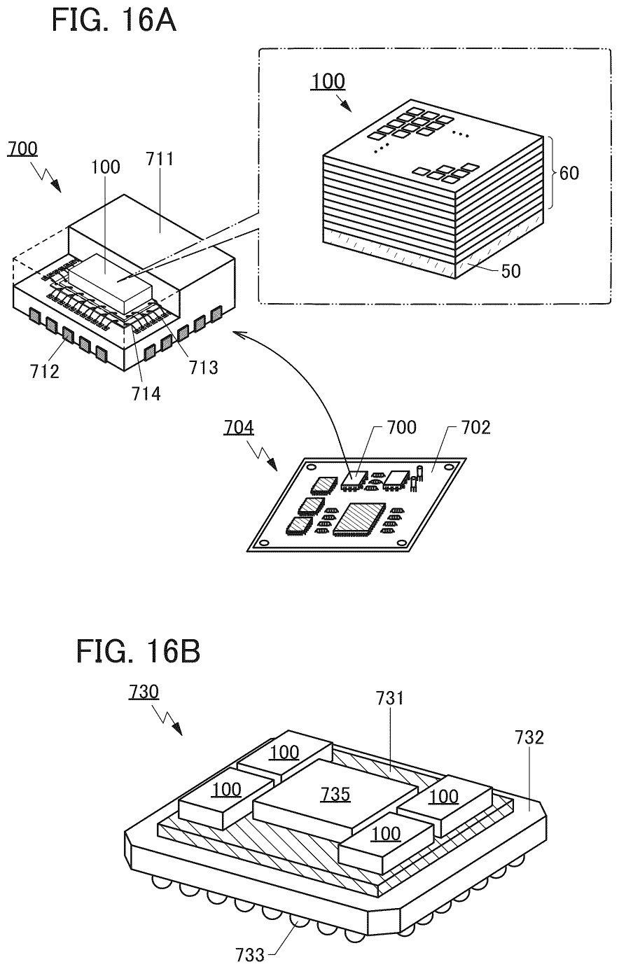

FIG. 16A is a perspective view of an electronic component 700 and a substrate (a circuit board 704) on which the electronic component 700 is mounted. The electronic component 700 illustrated in FIG. 16A includes the storage device 100, which is a kind of the semiconductor device of one embodiment of the present invention, in a mold 711. FIG. 16A omits illustrations of some components to show the inside of the electronic component 700. The electronic component 700 includes a land 712 outside the mold 711. The land 712 is electrically connected to an electrode pad 713, and the electrode pad 713 is electrically connected to the storage device 100 via a wire 714. The electronic component 700 is mounted on a printed circuit board 702, for example. A plurality of such electronic components are combined and electrically connected to each other on the printed circuit board 702, which forms the circuit board 704.

As described in the above embodiment, the storage device 100 includes the driver circuit layer 50, a memory layer 60, and the memory array 15.

FIG. 16B is a perspective view of an electronic component 730. The electronic component 730 is an example of a SiP (System in package) or an MCM (Multi Chip Module). In the electronic component 730, an interposer 731 is provided over a package board 732 (printed circuit board) and a semiconductor device 735 and a plurality of storage devices 100 are provided over the interposer 731.

The electronic component 730 using the storage device 100 as a high bandwidth memory (HBM) is illustrated as an example. An integrated circuit (a semiconductor device) such as a CPU, a GPU, or an FPGA can be used as the semiconductor device 735.

As the package board 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package board 732. Accordingly, the interposer is sometimes referred to as a “redistribution substrate” or an “intermediate substrate”. A through electrode may be provided in the interposer 731 to be used for electrically connecting the integrated circuit and the package board 732. In the case of using a silicon interposer, a through-silicon via (TSV) can also be used as the through electrode.

A silicon interposer is preferably used as the interposer 731. The silicon interposer can be manufactured at lower cost than an integrated circuit because it is not necessary to provide an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 100 and the semiconductor device 735 are preferably the same, for example.

An electrode 733 may be provided on the bottom portion of the package board 732 to mount the electronic component 730 on another substrate. FIG. 16B illustrates an example where the electrode 733 is formed of a solder ball. Solder balls are provided in a matrix on the bottom portion of the package board 732, whereby a BGA (Ball Grid Array) can be achieved. Alternatively, the electrode 733 may be formed of a conductive pin. When conductive pins are provided in a matrix on the bottom portion of the package board 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

This embodiment can be combined as appropriate with any of the other embodiments and the like described in this specification.

### Embodiment 5

In this embodiment, application examples of the storage device of one embodiment of the present invention are described.

The storage device of one embodiment of the present invention can be applied to, for example, storage devices of a variety of electronic devices (e.g., information terminals, computers, smartphones, e-book readers, digital still cameras, video cameras, video recording/reproducing devices, navigation systems, game machines, and the like). In addition, the storage device can also be used for image sensors, IoT (Internet of Things), healthcare-related devices, and the like. Note that here, the computers refer not only to tablet computers, laptop computers, and desktop computers, but also to large computers such as server systems.

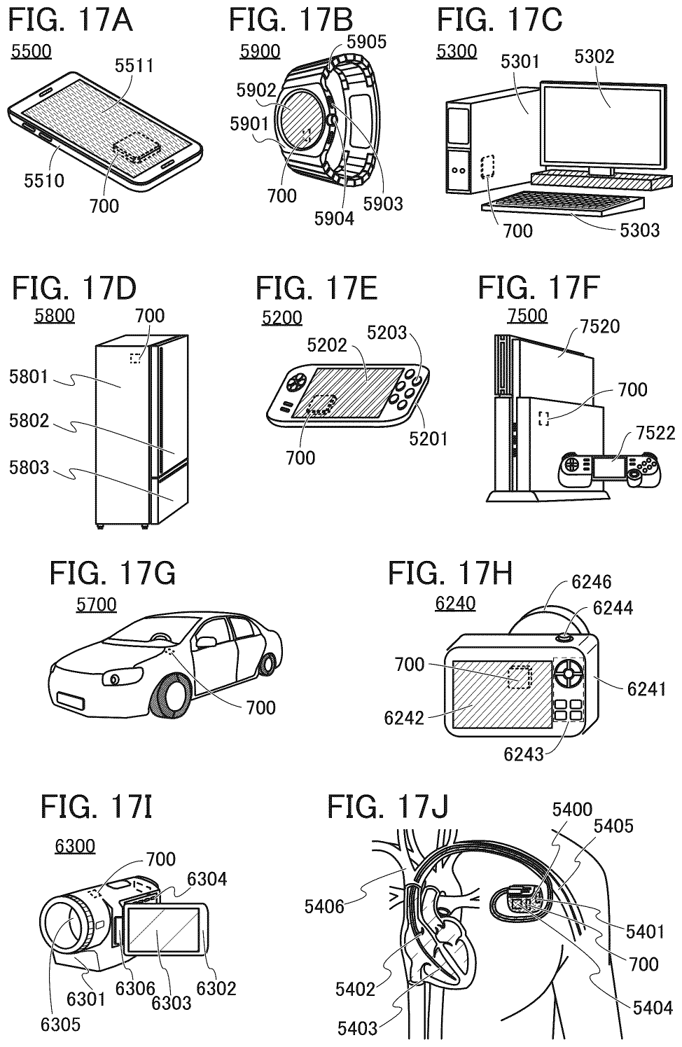

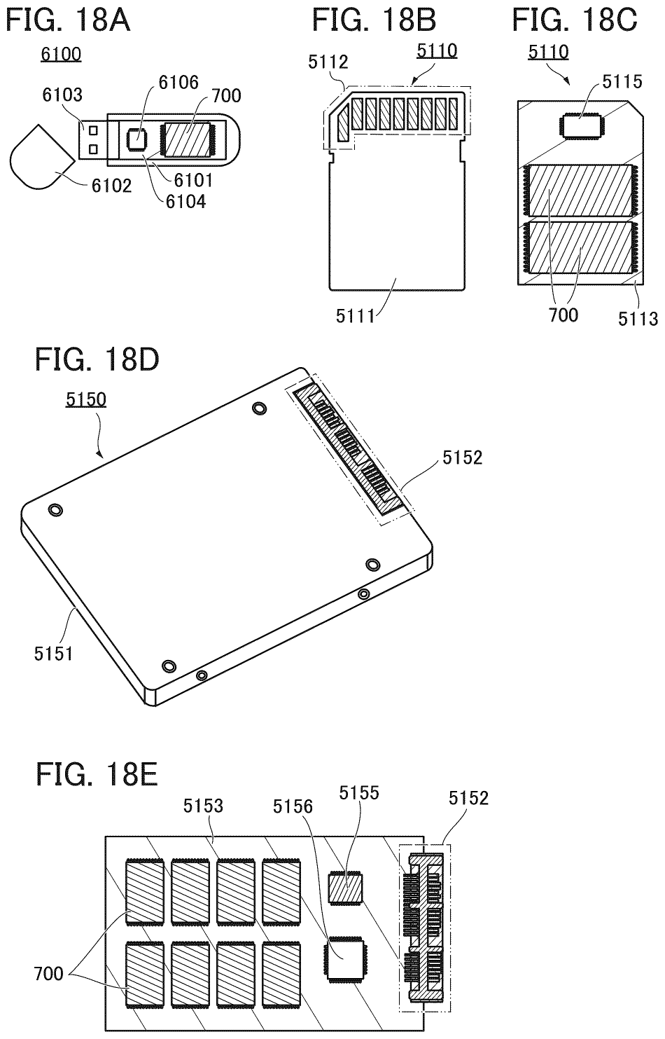

An example of an electronic device including the storage device of one embodiment of the present invention is described. Note that FIG. 17A to FIG. 17J and FIG. 18A to FIG. 18E each illustrate a state where the electronic component 700 or the electronic component 730, each of which includes the storage device, is included in an electronic device.

### [Cellular Phone]

An information terminal 5500 illustrated in FIG. 17A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By applying the storage device of one embodiment of the present invention to the information terminal 5500, the information terminal 5500 can retain a temporary file generated at the time of executing an application (e.g., a web browser's cache or the like).

### [Wearable Terminal]

In addition, FIG. 17B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by applying the storage device of one embodiment of the present invention to the wearable terminal.

### [Information Terminal]

In addition, FIG. 17C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application applying the storage device of one embodiment of the present invention to the desktop information terminal 5300.

Note that although the smartphone, the wearable terminal, and the desktop information terminal are respectively illustrated in FIG. 17A to FIG. 17C as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

In addition, FIG. 17D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The storage device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal and the like via the Internet. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, an audiovisual appliance, and the like.

### [Game Machine]

In addition, FIG. 17E illustrates a portable game machine 5200 as an example of a game machine. The portable game machine 5200 includes a housing 5201, a display portion 5202, a button 5203, and the like.

In addition, FIG. 17F illustrates a stationary game machine 7500 as another example of a game machine. The stationary game machine 7500 includes a main body 7520 and a controller 7522. Note that the controller 7522 can be connected to the main body 7520 with or without a wire. Furthermore, although not illustrated in FIG. 17F, the controller 7522 can include a display portion that displays a game image, and an input interface besides a button, such as a touch panel, a stick, a rotating knob, and a sliding knob, for example. Moreover, the shape of the controller 7522 is not limited to that illustrated in FIG. 17F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

In addition, videos displayed on the game machine can be output with a display apparatus such as a television device, a personal computer display, a game display, or a head-mounted display.

The storage device described in the above embodiment is employed for the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

Moreover, the storage device described in the above embodiment is employed for the portable game machine 5200 or the stationary game machine 7500, so that it is possible to retain a temporary file necessary for an arithmetic operation that occurs during game play.

As an example of a game machine, FIG. 17E illustrates a portable game machine. In addition, FIG. 17F illustrates a home-use stationary game machine. Note that an electronic device of one embodiment of the present invention is not limited thereto. Examples of the electronic device of one embodiment of the present invention include an arcade game machine installed in entertainment facilities (a game center, an amusement park, and the like), a throwing machine for batting practice installed in sports facilities, and the like.

### [Moving Vehicle]

The storage device described in the above embodiment can be used for a motor vehicle, which is a moving vehicle, and around the driver's seat in a motor vehicle.

FIG. 17G illustrates a motor vehicle 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the motor vehicle 5700. In addition, a display apparatus showing the above information may be provided around the driver's seat.

In particular, the display apparatus can compensate for the view obstructed by a pillar or the like, blind areas for the driver's seat, and the like by displaying a video from an image capturing device (not illustrated) provided for the motor vehicle 5700, which can increase safety. That is, display of an image from an image capturing device provided on the outside of the motor vehicle 5700 can fill in blind areas and increase safety.

The semiconductor device described in the above embodiments can temporarily hold information; thus, the storage device can be used to hold temporary data necessary in a system conducting automatic driving, navigation, and risk prediction for the motor vehicle 5700, for example. The display apparatus may be configured to display temporary information regarding navigation, risk prediction, or the like. Moreover, the semiconductor device may be configured to hold a video of a driving recorder provided in the motor vehicle 5700.

Note that although a motor vehicle is described above as an example of a moving vehicle, the moving vehicle is not limited to a motor vehicle. Examples of moving vehicles include a train, a monorail train, a ship, a flying object (a helicopter, an unmanned aircraft (a drone), an airplane, and a rocket), and the like.

### [Camera]

The storage device described in the above embodiment can be employed for a camera.

FIG. 17H illustrates a digital camera 6240 as an example of an image capturing device. The digital camera 6240 includes a housing 6241, a display portion 6242, operation switches 6243, a shutter button 6244, and the like, and a detachable lens 6246 is attached to the digital camera 6240. Note that, here, although the digital camera 6240 is configured such that the lens 6246 is detachable from the housing 6241 for replacement, the lens 6246 may be integrated with the housing 6241. In addition, the digital camera 6240 can be additionally equipped with a stroboscope, a viewfinder, or the like.

When the storage device described in the above embodiment is employed for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The storage device described in the above embodiment can be employed for a video camera.

FIG. 17I illustrates a video camera 6300 as an example of an image capturing device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

When images captured by the video camera 6300 are recorded, the images need to be encoded in accordance with a data recording format. With the use of the above semiconductor device, the video camera 6300 can retain a temporary file generated in encoding.

### [ICD]

The storage device described in the above embodiment can be employed for an implantable cardioverter-defibrillator (ICD).

FIG. 17J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, and the time taken for the treatment, for example, can be stored in the electronic component 700.

In addition, the antenna 5404 can receive power, and the battery 5401 is charged with the power. Furthermore, when the ICD main unit 5400 includes a plurality of batteries, safety can be increased. Specifically, even when one of the batteries in the ICD main unit 5400 is dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Expansion Device for PC]

The semiconductor device described in the above embodiment can be employed for a calculator such as a PC (Personal Computer) and an expansion device for an information terminal.

FIG. 18A illustrates, as an example of the expansion device, a portable expansion device 6100 that includes a chip capable of holding information and is externally provided on a PC. The expansion device 6100 can store information using the chip when connected to a PC with a USB (Universal Serial Bus) or the like, for example. Note that FIG. 18A illustrates the portable expansion device 6100; however, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in the above embodiment. For example, the substrate 6104 is provided with the electronic component 700 and a controller chip 6106. The USB connector 6103 functions as an interface for connection to an external device.

### [SD Card]

The storage device described in the above embodiment can be employed for an SD card that can be attached to an electronic device such as an information terminal or a digital camera.

FIG. 18B is a schematic external view of an SD card, and FIG. 18C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a storage device and a circuit for driving the storage device. For example, the electronic components 700 and a controller chip 5115 are attached to the substrate 5113. Note that the circuit structures of the electronic components 700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic component 700.

When the electronic components 700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The storage device described in the above embodiment can be employed for an SSD (Solid State Drive) that can be attached to an electronic device such as an information terminal.

FIG. 18D is a schematic external view of an SSD, and FIG. 18E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a storage device and a circuit for driving the storage device. For example, the electronic components 700, a memory chip 5155, and a controller chip 5156 are attached to the substrate 5153. When the electronic components 700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, and the like are incorporated in the controller chip 5156. Note that the circuit structures of the electronic components 700, the memory chip 5155, and the controller chip 5115 are not limited to those described above, and the circuit structures can be changed as appropriate according to circumstances. For example, a memory functioning as a work memory may also be provided in the controller chip 5156.

### [Computer]

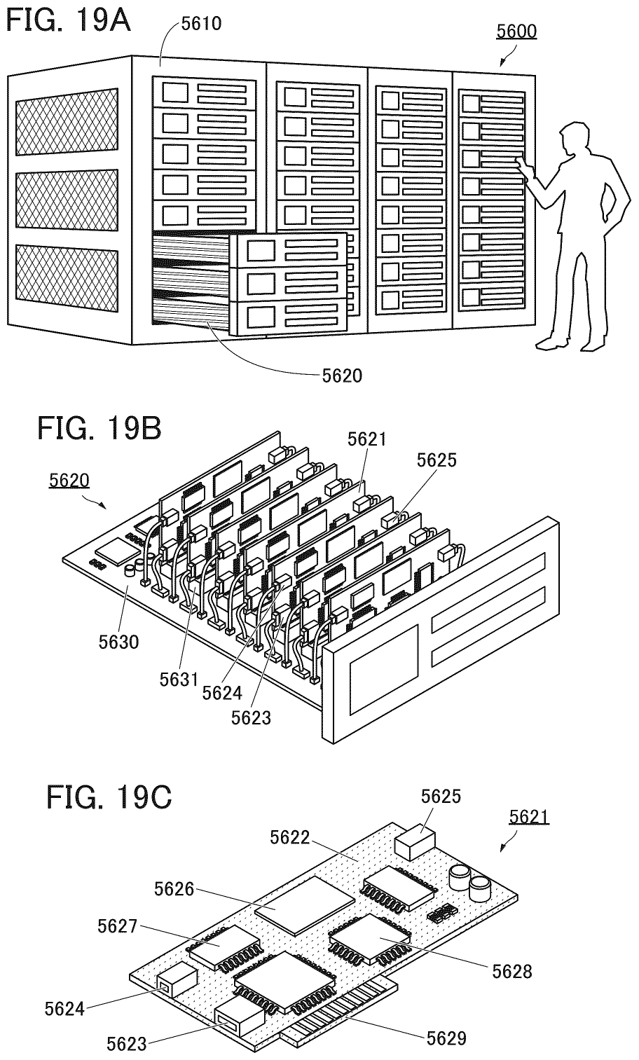

A computer 5600 illustrated in FIG. 19A is an example of a large computer. In the computer 5600, a plurality of rack mount computers 5620 are stored in a rack 5610.

The computer 5620 can have a structure in a perspective view illustrated in FIG. 19B, for example. In FIG. 19B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 19C is an example of a processing board provided with a CPU, a GPU, a storage device, and the like. The PC card 5621 includes a board 5622. In addition, the board 5622 includes the connection terminal 5623, the connection terminal 5624, the connection terminal 5625, a semiconductor device 5626, a semiconductor device 5627, a semiconductor device 5628, and a connection terminal 5629. Note that FIG. 19C also illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe or the like.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), SCSI (Small Computer System Interface), and the like. In the case where video signals are output from the connection terminal 5623, the connection terminal 5624, and the connection terminal 5625, an example of the standard therefor is HDMI (registered trademark) or the like.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA (Field Programmable Gate Array), a GPU, a CPU, and the like. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device or the like. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The storage device of one embodiment of the present invention is used in a variety of electronic devices or the like described above, so that a reduction in size and a reduction in power consumption of the electronic device can be achieved. In addition, since the storage device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the storage device of one embodiment of the present invention can achieve an electronic device that operates stably even in a high temperature environment. Thus, the reliability of the electronic devices can be increased.

This embodiment can be combined as appropriate with any of the other embodiments and the like described in this specification.

### REFERENCE NUMERALS

10: memory cell, 15: memory array, 100: storage device, 150: capacitor, 153: insulator, 154: insulator, 158: opening, 160: conductor, 200: transistor

1. A storage device comprising:
N memory layers, wherein N is an integer greater than or equal to 2;
a plurality of first wirings extending in a first direction that is a stacking direction of the N memory layers;
a plurality of second wirings extending in the first direction;
a plurality of third wirings extending in the first direction;
a plurality of fourth wirings extending in a second direction intersecting with the first direction; and
a plurality of fifth wirings extending in the second direction,
wherein each of the N memory layers comprises a plurality of memory cells arranged in a matrix,
wherein each of the plurality of memory cells comprises a first transistor, a second transistor, and a capacitor,
wherein a gate of the first transistor is electrically connected to one of the plurality of fourth wirings,
wherein one of a source and a drain of the first transistor is electrically connected to one of the plurality of first wirings through a first conductor,
wherein one electrode of the capacitor is electrically connected to one of the plurality of fifth wirings,
wherein the other electrode of the capacitor is electrically connected to the other of the source and the drain of the first transistor and a gate of the second transistor,
wherein one of a source and a drain of the second transistor is electrically connected to one of the plurality of second wirings,
wherein the other of the source and the drain of the second transistor is electrically connected to one of the plurality of third wirings, and
wherein the first conductor comprises a region where at least one of a top surface, a side surface, and a bottom surface of the first conductor is in contact with the one of the plurality of first wirings.

2. The storage device according to claim 1,
wherein the one of the source and the drain of the second transistor is electrically connected to the one of the plurality of second wirings through a second conductor, and
wherein the second conductor comprises a region where at least one of a top surface, a side surface, and a bottom surface of the second conductor is in contact with the one of the plurality of second wirings.

3. The storage device according to claim 1,
wherein the other of the source and the drain of the second transistor is electrically connected to the one of the plurality of third wirings through a third conductor, and
wherein the third conductor comprises a region where at least one of a top surface, a side surface, and a bottom surface of the third conductor is in contact with the one of the plurality of third wirings.

4. The storage device according to claim 1,
wherein the first transistor comprises a back gate.

5. The storage device according to claim 1,
wherein the first transistor comprises an oxide semiconductor.
